(19) United States
(12) Patent Application Publication
(10) Pub. No.: US 2024/0387086 A1
(43) Pub. Date: Nov. 21, 2024

(54) DRIVING ELEMENT AND DRIVING DEVICE

(71) Applicant: Panasonic Intellectual Property Management Co., Ltd., Osaka (JP)

(72) Inventor: Kentaro NAKANISHI, Nara (JP)

(21) Appl. No.: 18/789,279

(22) Filed: Jul. 30, 2024

Related U.S. Application Data
(63) Continuation of application No. PCT/JP2023/001126, filed on Jan. 17, 2023.

(30) Foreign Application Priority Data
Feb. 3, 2022 (JP) 2022-015634

(51) Int. Cl. H01F 7/02; H01F 7/20; H10N 30/20; H10N 30/80; H10N 30/88

(52) U.S. Cl. CPC H01F 7/02; H01F 7/20; H10N 30/20; H10N 30/802; H10N 30/88

(57) ABSTRACT

A driving element includes a fixation part, a vibration plate supported by the fixation part, a driving part placed on the vibration plate and configured to vibrate the vibration plate, a movable part placed in the vibration plate and configured to be rotated by vibration of the vibration plate, and a displacement suppression part configured to suppress displacement of the vibration plate from a neutral position by a force generated by action of a magnet.

### CROSS REFERENCE TO RELATED APPLICATION

This application is a continuation of International Application No. PCT/JP2023/001126 filed on Jan. 17, 2023, entitled “DRIVING ELEMENT AND DRIVING DEVICE”, which claims priority under 35 U.S.C. Section 119 of Japanese Patent Application No. 2022-015634 filed on Feb. 3, 2022, entitled “DRIVING ELEMENT AND DRIVING DEVICE”. The disclosures of the above applications are incorporated herein by reference.

### BACKGROUND OF THE INVENTION

### Field of the Invention

The present invention relates to a driving element that drives a movable part about a rotation axis, and a driving device.

### Description of Related Art

A driving element that drives a movable part about a rotation axis has been known. In this type of driving element, a stopper is provided such that the movable part is not displaced more than necessary when an impact is applied from the outside. For example, Japanese Laid-Open Patent Publication No. 2002-40354 describes an optical scanner that includes: a movable plate having a reflection surface; a support supporting the movable plate such that the movable plate can oscillate; and a restriction member provided for the movable plate.

In the driving element as described above, when an impact is applied to the driving element, the stopper suppresses excessive displacement of the movable part, but the movable part and the stopper may be damaged due to the movable part colliding with the stopper.

### SUMMARY OF THE INVENTION

A first aspect of the present invention is directed to a driving element. The driving element according to this aspect includes: a fixation part; a vibration plate supported by the fixation part; a driving part placed on the vibration plate and configured to vibrate the vibration plate; a movable part placed in the vibration plate and configured to be rotated by vibration of the vibration plate; and a displacement suppression part configured to suppress displacement of the vibration plate from a neutral position by a force generated by action of a magnet.

With the driving element according to this aspect, displacement of the vibration plate from the neutral position is suppressed by the force generated by the action of the magnet. Accordingly, when an impact is applied to the driving element, excessive displacement of the movable part can be smoothly suppressed.

A second aspect of the present invention is directed to a driving device. The driving device according to this aspect includes the above driving element according to the first aspect. Here, the displacement suppression part includes a wire for braking placed on the vibration plate, and the magnet exerts a magnetic flux on the wire. When a current flows through the wire, the wire and the magnet generate a Lorentz force that suppresses displacement of the vibration plate from the neutral position. The driving device includes a current supply part configured to supply the current to the wire.

With the driving device according to this aspect, the same effects as those of the above first aspect are achieved.

A third aspect of the present invention is directed to a driving device. The driving device according to this aspect includes the above driving element according to the first aspect. Here, the displacement suppression part includes a magnet thin film placed on the vibration plate. Displacement of the vibration plate from the neutral position is suppressed by a magnetic repulsive force generated between the magnet thin film and the magnet. The driving device includes a current supply part. The magnet includes a coil, and the current supply part supplies a current to the coil.

With the driving device according to this aspect, the same effects as those of the above first aspect are achieved.

The effects and the significance of the present invention will be further clarified by the description of the embodiments below. However, the embodiments below are merely examples for implementing the present invention. The present invention is not limited to the description of the embodiments below in any way.

### BRIEF DESCRIPTION OF THE DRAWINGS

FIG. 1 is a perspective view schematically showing a configuration of a structure according to Embodiment 1.

FIG. 2 is a perspective view schematically showing the configuration of the structure according to Embodiment 1.

FIG. 3A is a side view schematically showing a C1-C2 cross-section at a vibration part in FIG. 2 according to Embodiment 1.

FIG. 3B is a side view schematically showing the C1-C2 cross-section in FIG. 2 according to a modification of Embodiment 1.

FIG. 4 is a perspective view schematically showing a configuration of a driving element according to Embodiment 1.

FIG. 5 is a plan view schematically showing the configuration of the driving element according to Embodiment 1.

FIG. 6 is a block diagram showing the configuration of the driving element according to Embodiment 1.

FIG. 7 is a perspective view for schematically illustrating suppression of excessive displacement of a vibration plate by Lorentz forces according to Embodiment 1.

FIG. 8 is a perspective view schematically showing a configuration of a structure according to Embodiment 2.

FIG. 9 is a perspective view schematically showing a configuration of a driving element according to Embodiment 2.

FIG. 10 is a perspective view for schematically illustrating suppression of excessive displacement of a vibration plate by Lorentz forces according to Embodiment 2.

FIG. 11 is a perspective view schematically showing a configuration of a driving element according to Embodiment 3.

FIG. 12 is a side view schematically showing a configuration of a tubular member in which a coil is installed, according to Embodiment 3.

FIG. 13 is a perspective view for schematically illustrating suppression of excessive displacement of a vibration plate by Lorentz forces according to Embodiment 3.

FIG. 14 is a perspective view schematically showing a configuration of a driving element according to Embodiment 4.

FIG. 15 is a plan view schematically showing a coil wound around the outer surface of a frame-shaped fixation part, according to Embodiment 4.

FIG. 16 is a perspective view for schematically illustrating suppression of excessive displacement of a vibration plate by Lorentz forces according to Embodiment 4.

FIG. 17 is a perspective view schematically showing a configuration of a driving element according to Embodiment 5.

FIG. 18 is a plan view schematically showing a configuration of a coil wound in a circular shape on a substrate, according to Embodiment 5.

FIG. 19 is a perspective view for schematically illustrating suppression of excessive displacement of a vibration plate by Lorentz forces according to Embodiment 5.

FIG. 20 is a perspective view schematically showing a configuration of a driving element according to Embodiment 6.

FIG. 21 is a perspective view for schematically illustrating suppression of excessive displacement of a vibration plate by Lorentz forces according to Embodiment 6.

FIG. 22 is a perspective view schematically showing a configuration of a driving element according to Embodiment 7.

FIG. 23 is a perspective view for schematically illustrating suppression of excessive displacement of a vibration plate by Lorentz forces according to Embodiment 7.

FIG. 24 is a plan view schematically showing a configuration of a driving element according to Embodiment 8.

FIG. 25 is a plan view schematically showing a configuration of a driving element according to Embodiment 9.

FIG. 26 is a side view schematically showing a C1-C2 cross-section at a vibration part in FIG. 25 according to Embodiment 9.

It should be noted that the drawings are solely for description and do not limit the scope of the present invention by any degree.

### DETAILED DESCRIPTION

Hereinafter, embodiments of the present invention will be described with reference to the drawings. For convenience, in each drawing, X, Y, and Z axes that are orthogonal to each other are additionally shown. The Z-axis positive direction is the vertical upward direction.

### Embodiment 1

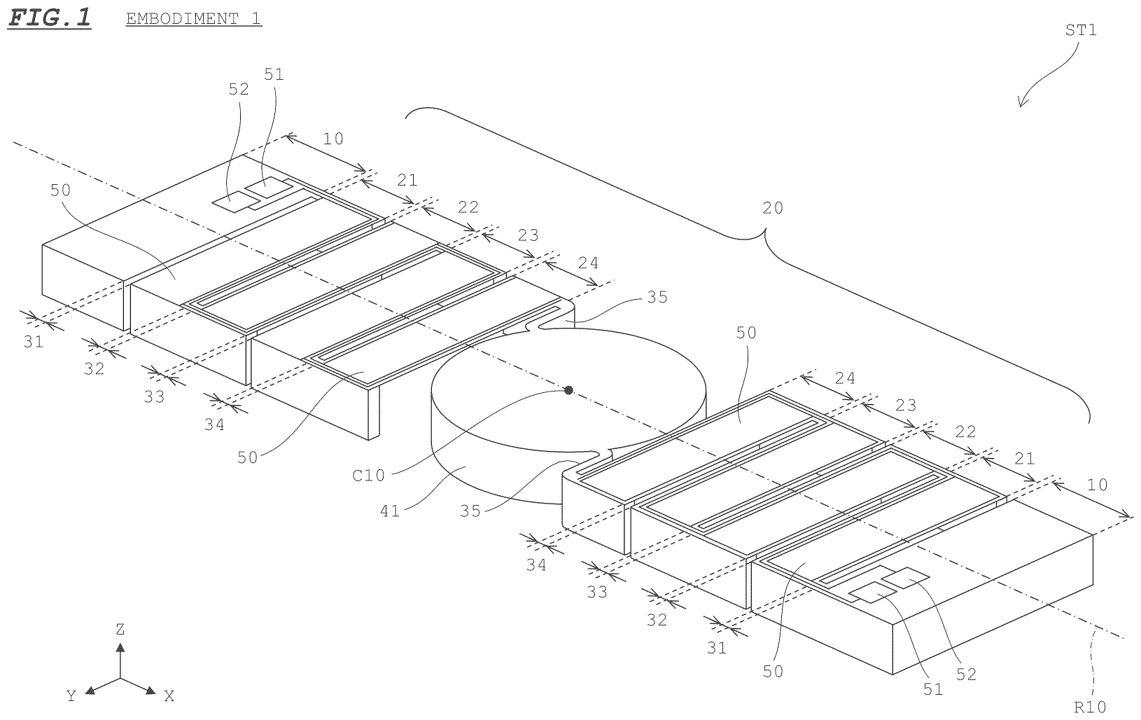

With reference to FIG. 1 to FIG. 4, a configuration of a driving element 1 will be described.

FIG. 1 is a perspective view schematically showing a configuration of a structure ST1.

The structure ST1 includes a fixation part 10, a vibration plate 20, and four driving parts 50. The structure ST1 is configured to be symmetrical in the X-axis direction and the Y-axis direction about a center C10.

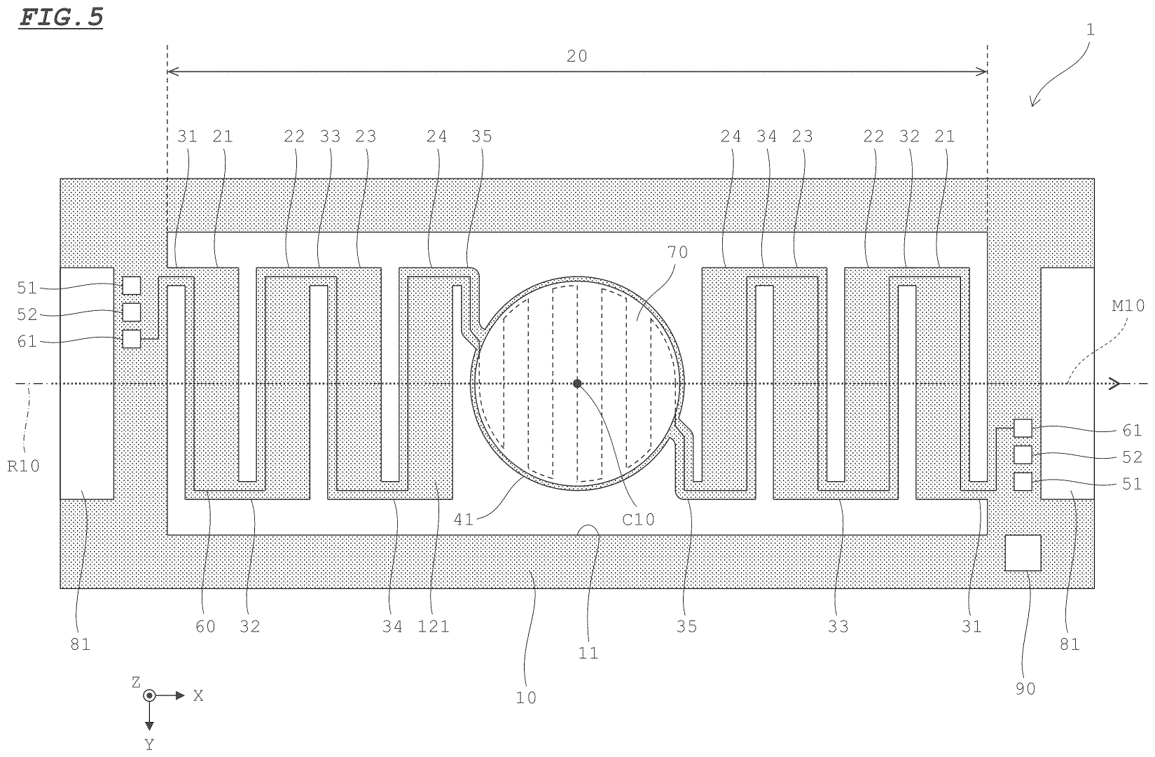

The fixation part 10 is configured in a frame shape as described later with reference to FIG. 5. In FIG. 1, the fixation part 10 is illustrated only in the vicinity of portions connected to the vibration plate 20.

The vibration plate 20 is located inside the frame shape of the fixation part 10 in a plan view, and an end portion on the X-axis positive side and an end portion on the X-axis negative side of the vibration plate 20 are supported by the fixation part 10. The vibration plate 20 includes a movable part 41 at the position of the center C10. The movable part 41 rotates about a rotation axis R10 which passes through the center C10 and extends in the X-axis direction.

The vibration plate 20 has a meander shape. The vibration plate 20 includes vibration parts 21 to 24 and connection parts 31 to 35 on each of the X-axis positive side and the X-axis negative side of the movable part 41. FIG. 1 shows a state where the vibration plate 20 is at a neutral position. The neutral position refers to a state where each part of the vibration plate 20 is parallel to the X-Y plane.

The vibration parts 21 to 24 each have a rectangular shape that is longer in the Y-axis direction than in the X-axis direction. The vibration part 21 on the X-axis negative side of the movable part 41 is connected at an end portion on the Y-axis negative side thereof to the fixation part 10 by the connection part 31. The vibration part 22 on the X-axis negative side of the movable part 41 is connected at an end portion on the Y-axis positive side thereof to the vibration part 21 by the connection part 32. The vibration part 23 on the X-axis negative side of the movable part 41 is connected at an end portion on the Y-axis negative side thereof to the vibration part 22 by the connection part 33. The vibration part 24 on the X-axis negative side of the movable part 41 is connected at an end portion on the Y-axis positive side thereof to the vibration part 23 by the connection part 34. The vibration part 24 on the X-axis negative side of the movable part 41 is connected at an end portion on the Y-axis negative side thereof to the movable part 41 by the connection part 35. The vibration parts 21 to 24 and the connection parts 31 to 35 on the X-axis positive side of the movable part 41 are point symmetrical with the vibration parts 21 to 24 and the connection parts 31 to 35 on the X-axis negative side of the movable part 41 about the center C10.

Two driving parts 50 are placed on the upper surfaces of the vibration parts 21 to 24 and the connection parts 31 to 35 on the X-axis negative side of the movable part 41, and two driving parts 50 are placed on the upper surfaces of the vibration parts 21 to 24 and the connection parts 31 to 35 on the X-axis positive side of the movable part 41. The driving parts 50 rotate the movable part 41. Each driving part 50 is a so-called piezoelectric transducer. A piezoelectric transducer is sometimes called piezoelectric actuator. On the X-axis negative side of the movable part 41, the two driving parts 50 are connected to electrodes 51 and 52 placed on the fixation part 10, respectively. Similarly, on the X-axis positive side of the movable part 41, the two driving parts 50 are connected to electrodes 51 and 52 placed on the fixation part 10, respectively.

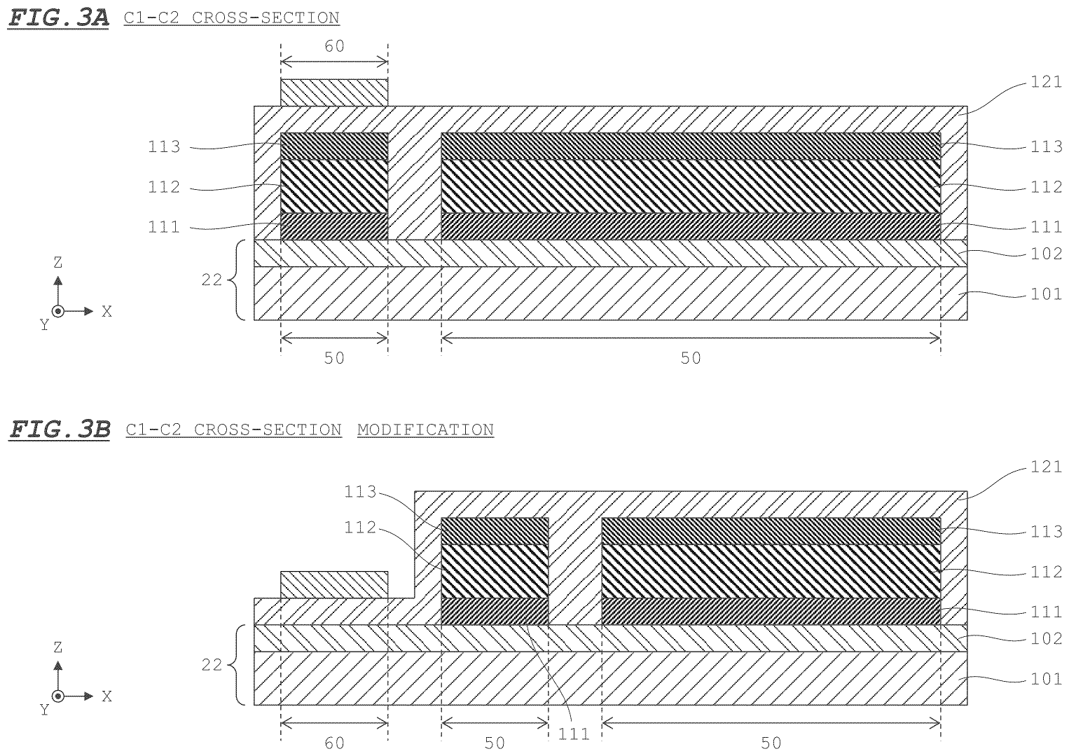

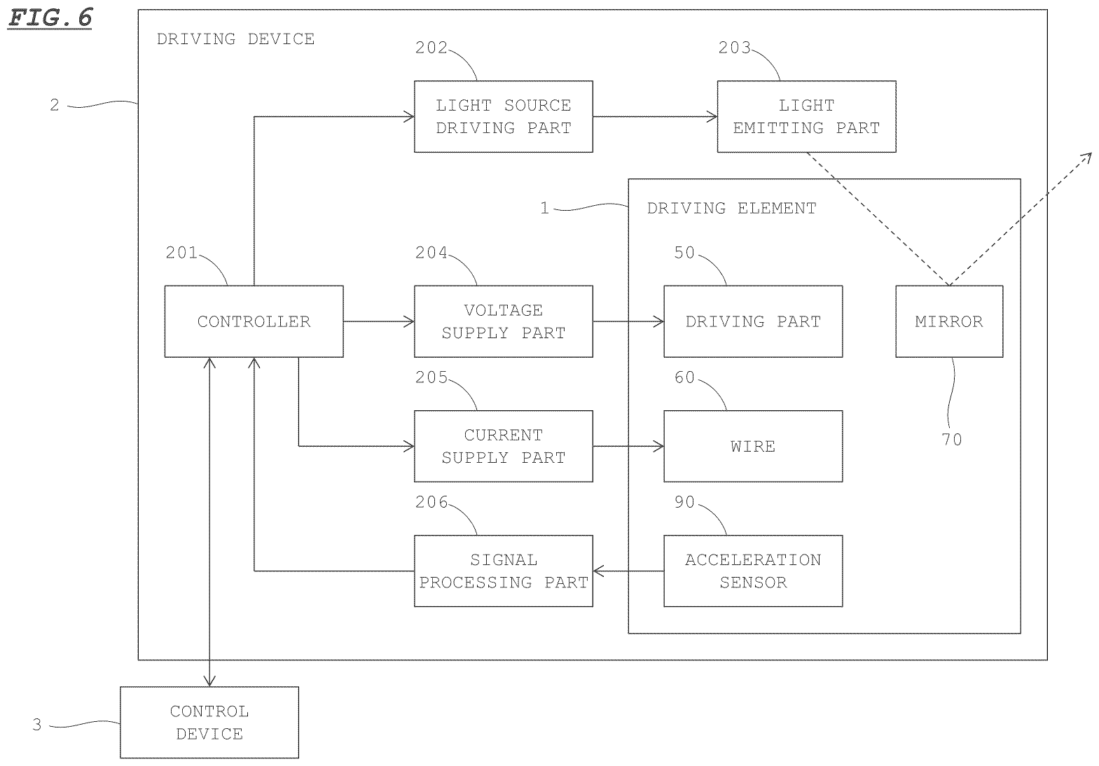

Each driving part 50 includes a lower electrode 111, a piezoelectric layer 112, and an upper electrode 113 as described later with reference to FIG. 3. At the position of the electrodes 51 and 52, a voltage supply part 204 of a driving device 2 (see FIG. 6) is connected to the lower electrode 111 and the upper electrode 113 of the driving part 50. For example, the lower electrode 111 is connected to a ground, and a voltage is applied to the upper electrode 113. Accordingly, the voltage is applied to the piezoelectric layer 112 interposed between the lower electrode 111 and the upper electrode 113, and the piezoelectric layer 112 is deformed.

The driving parts 50 connected to the electrodes 51 are wider in the X-axis direction on the vibration parts 22 and 24, and are narrower in the X-axis direction on the vibration parts 21 and 23. The driving parts 50 connected to the electrodes 52 are wider in the X-axis direction on the vibration parts 21 and 23, and are narrower in the X-axis direction on the vibration parts 22 and 24. Therefore, the driving parts 50 connected to the electrodes 51 mainly vibrate the vibration parts 22 and 24, and the driving parts 50 connected to the electrodes 52 mainly vibrate the vibration parts 21 and 23. Thus, when a drive signal (voltage) is applied via each electrode 51 to the driving part 50 connected to the electrode 51, the piezoelectric layer 112 is deformed in this driving part 50, and the vibration parts 22 and 24 vibrate so as to bend. Meanwhile, when a drive signal (voltage) is applied via each electrode 52 to the driving part 50 connected to the electrode 52, the piezoelectric layer 112 in this driving part 50 is deformed, and the vibration parts 21 and 23 vibrate so as to bend.

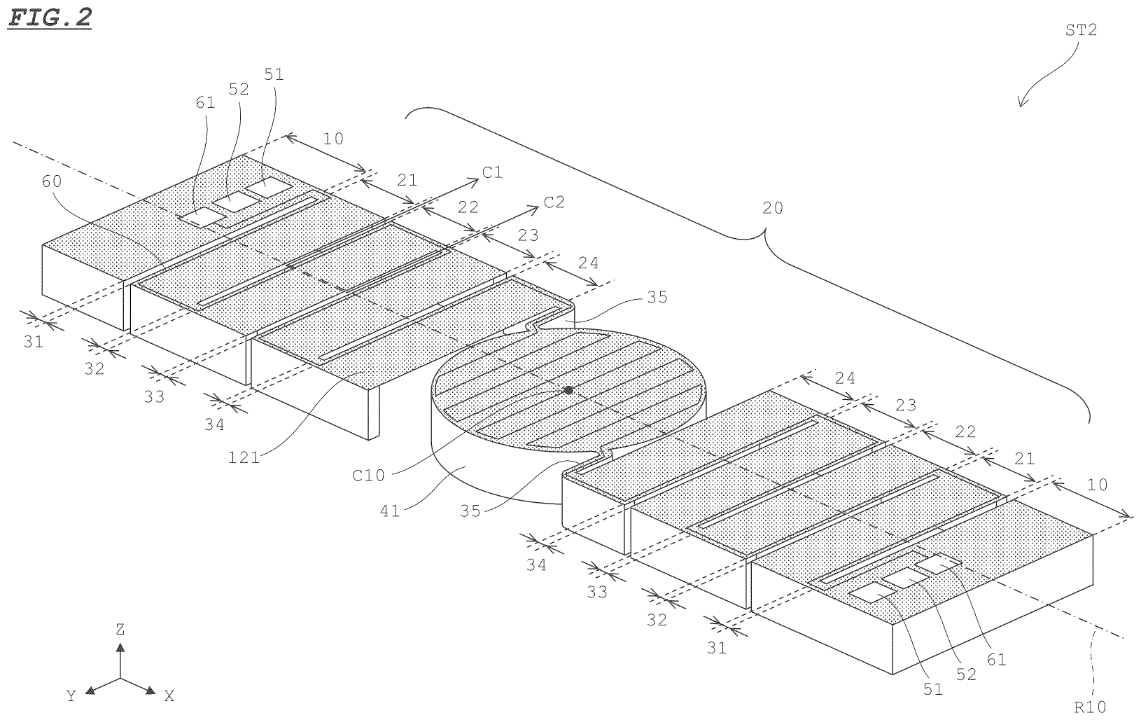

FIG. 2 is a perspective view schematically showing a configuration of a structure ST2.

The structure ST2 is configured by forming an insulating layer 121 on the upper surface of the structure ST1 in FIG. 1 and forming a wire 60 on the upper surface of the insulating layer 121. The insulating layer 121 is not formed on the upper surfaces of the electrodes 51 and 52. In FIG. 2, the insulating layer 121 is illustrated by hatching.

An end portion on the X-axis negative side and an end portion on the X-axis positive side of the wire 60 are connected to electrodes 61 at the fixation part 10. The wire 60 extends from one electrode 61 to the other electrode 61, and is formed on the upper surface (surface on the Z-axis positive side) of the insulating layer 121 on the vibration parts 21 to 24, the connection parts 31 to 35, and the movable part 41.

FIG. 3A is a side view schematically showing a C1-C2 cross-section at the vibration part 22 in FIG. 2. The vibration parts 21, 23, and 24 have substantially the same configuration as the vibration part 22, and thus only the vibration part 22 will be described below for convenience.

The vibration part 22 is composed of a base layer 101 and an insulating layer 102 installed on the upper surface of the base layer 101. The base layer 101 is composed of, for example, silicon (Si), and the insulating layer 102 is composed of, for example, a thermal oxide film (SiO₂).

The vibration parts 21 to 24, the connection parts 31 to 35, the movable part 41, and the fixation part 10 all include the common base layer 101 and insulating layer 102. That is, the base layer 101 and the insulating layer 102, which form the vibration parts 21 to 24, the connection parts 31 to 35, the movable part 41, and the fixation part 10, are integrally formed. Another base layer is further provided on the lower surface of the base layer 101 at the connection parts 31 to 35, the outer circumference of the movable part 41, and the fixation part 10 such that the thickness is increased.

Each driving part 50 is composed of the lower electrode 111, the piezoelectric layer 112, and the upper electrode 113. The lower electrode 111 is formed on the upper surface of the insulating layer 102, and the piezoelectric layer 112 is formed between the lower electrode 111 and the upper electrode 113. The lower electrode 111 is composed of, for example, platinum (Pt). The piezoelectric layer 112 is composed of, for example, PZT (lead zirconate titanate: Pb(Zr, Ti)O₃). The upper electrode 113 is composed of, for example, gold (Au).

The wider driving part 50 in FIG. 3A is connected to the electrode 51 (see FIG. 1), and the narrower driving part 50 in FIG. 3A is connected to the electrode 52. When a drive signal (voltage) is applied to the two driving parts 50 via the electrodes 51 and 52, the piezoelectric layer 112 in each driving part 50 is deformed, and the vibration parts 21 to 24 vibrate so as to bend. At this time, the narrow driving part 50 at each of the vibration parts 21 to 24 is almost not deformed and thus almost does not contribute to bending of the vibration parts 21 to 24.

The insulating layer 121 is formed on the upper surface side of the driving parts 50. The insulating layer 121 is composed of, for example, SiN or Al₂O₃.

The wire 60 is formed on the upper surface of the insulating layer 121. The wire 60 is composed of, for example, gold (Au).

In FIG. 2 and FIG. 3A, the wire 60 is placed so as to pass above the narrower driving part 50, but the placement position of the wire 60 is not limited thereto, and the wire 60 may be placed so as to pass above the wider driving part 50.

In FIG. 3A, the wire 60 and the driving part 50 are placed so as to overlap each other in a plan view, but as shown in FIG. 3B, the wire 60 and the driving part 50 may be placed such that the wire 60 and the driving part 50 do not overlap each other, that is, the wire 60 and the driving part 50 are aligned in the X-axis direction in a plan view.

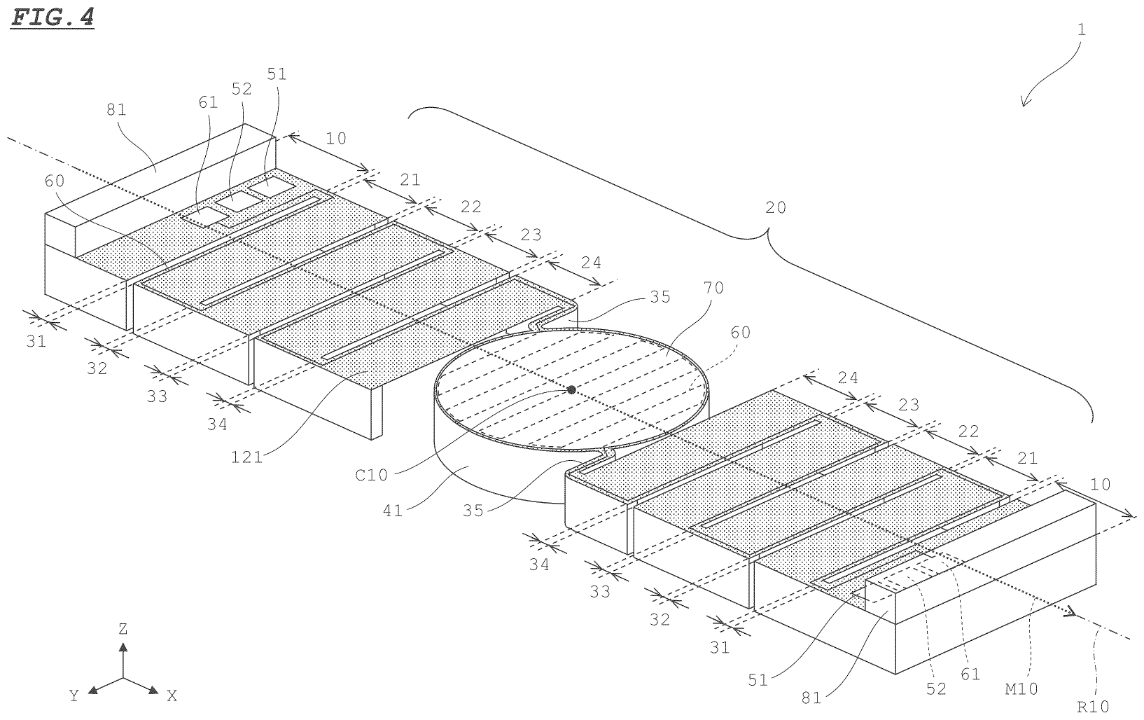

FIG. 4 is a perspective view schematically showing a configuration of the driving element 1.

After another insulating film is further formed on the upper surface side of the insulating layer 121 and the wire 60 on the movable part 41 shown in FIG. 2, a mirror 70 is formed on the upper surface of the other insulating film. The mirror 70 is composed of a metal film that reflects light, and the upper surface of the mirror 70 is a reflection surface. In FIG. 4, the wire 60 located on the lower surface side of the mirror 70 is shown by a dashed line for convenience. Since the wire 60 is placed on the lower surface side of the mirror 70, slight irregularities are formed on the upper surface of the mirror 70. However, the irregularities formed on the upper surface of the mirror 70 are at a minute level compared to the size of the mirror 70, so that light incident on the mirror 70 is properly reflected by the mirror 70.

A pair of permanent magnets 81 are installed on the upper surface side of the fixation part 10 located on the X-axis positive side and the X-axis negative side of the vibration plate 20. The pair of permanent magnets 81 generate a magnetic flux M10, and are placed such that the direction of the magnetic flux M10 is the X-axis positive direction through the center C10.

FIG. 5 is a plan view schematically showing the configuration of the driving element 1.

The fixation part 10 has a frame shape, and the vibration plate 20 is positioned in an opening 11 which penetrates the fixation part 10 in the Z-axis direction at the center of the fixation part 10. An acceleration sensor 90 is installed on the fixation part 10. Thus, the driving element 1 is completed.

FIG. 6 is a block diagram showing a configuration of the driving device 2.

The driving device 2 includes the driving element 1, a controller 201, a light source driving part 202, a light emitting part 203, the voltage supply part 204, a current supply part 205, and a signal processing part 206.

The light emitting part 203 includes a light source, a collimator lens, etc., and applies light to the mirror 70. The light source driving part 202 drives the light source of the light emitting part 203 in accordance with an instruction signal from the controller 201.

Cables connected to the voltage supply part 204 are connected to the upper surfaces of the electrodes 51 and 52 (see FIGS. 4 and 5) of the driving element 1 by wire bonding. Accordingly, the voltage supply part 204 is individually connected to the four driving parts 50. A BGA substrate or substrate with through-wiring, which is connected to the voltage supply part 204, may be connected to the upper surfaces of the electrodes 51 and 52 by metal bonding. The voltage supply part 204 applies a drive signal (voltage) to the piezoelectric layer 112 of each driving part 50 in accordance with an instruction signal from the controller 201. Accordingly, the piezoelectric layer 112 of each driving part 50 is deformed by an inverse piezoelectric effect, and the vibration parts 21 to 24 vibrate so as to bend.

Specifically, drive signals having the same phase are applied to the two driving parts 50 connected to the two electrodes 51 such that the vibration parts 22 and 24 on the X-axis negative side of the movable part 41 and the vibration parts 22 and 24 on the X-axis positive side of the movable part 41 vibrate in the same direction in the Z-axis direction. In addition, drive signals having the same phase are applied to the two driving parts 50 connected to the two electrodes 52 such that the vibration parts 21 and 23 on the X-axis negative side of the movable part 41 and the vibration parts 21 and 23 on the X-axis positive side of the movable part 41 vibrate in the same direction in the Z-axis direction. Moreover, drive signals having opposite phases are applied to the two driving parts 50 connected to the electrodes 51 and the two driving parts 50 connected to the electrodes 52 such that the vibration parts 22 and 24 and the vibration parts 21 and 23 vibrate in opposite directions in the Z-axis direction. Accordingly, the movable part 41 and the mirror 70 rotate about the rotation axis R10, so that the direction of light incident on the mirror 70 is changed in accordance with the rotation angle of the mirror 70.

Cables connected to the current supply part 205 are connected to the upper surfaces of the electrodes 61 (see FIGS. 4 and 5) of the driving element 1 by wire bonding. Accordingly, the current supply part 205 is connected to the wire 60. A BGA substrate or substrate with through-wiring, which is connected to the current supply part 205, may be connected to the upper surfaces of the electrodes 61 by metal bonding. The current supply part 205 causes a drive signal (current) to flow from the electrode 61 on the X-axis negative side through the wire 60 to the electrode 61 on the X-axis positive side, in accordance with an instruction signal from the controller 201. Accordingly, Lorentz forces are generated at the wire 60 as described later.

The signal processing part 206 is connected to the acceleration sensor 90 via a cable or substrate. The acceleration sensor 90 is, for example, a piezoelectric type acceleration sensor, and outputs a signal corresponding to acceleration in an arbitrary direction. The acceleration sensor 90 outputs a signal corresponding to the acceleration caused by an impact applied to the driving element 1. The signal processing part 206 performs a process such as A/D conversion on the signal from the acceleration sensor 90, and outputs a signal resulting from the process as a detection signal to the signal processing part 206.

The controller 201 is composed of, for example, a microcomputer or FPGA. The controller 201 controls the light source driving part 202 and the voltage supply part 204 based on an instruction signal from an external control device 3 such that the light emitted from the light emitting part 203 and reflected by the mirror 70 forms a desired image in a target area.

Here, in the driving element 1, when an impact is applied from the outside, the vibration plate 20 may be excessively displaced, resulting in damage to the vibration plate 20. To prevent this, for example, a stopper for suppressing excessive displacement of the vibration plate 20 can be provided. However, with this configuration, the vibration plate 20 and the stopper may be damaged due to contact between the vibration plate 20 and the stopper.

In contrast, in Embodiment 1, the wire 60 for braking is placed on the vibration plate 20, and the permanent magnets 81 which generate the magnetic flux M10 in the wire 60 are placed. When the controller 201 determines that an impact is applied to the driving element 1, based on the detection signal corresponding to the acceleration and outputted from the signal processing part 206, the controller 201 controls the current supply part 205 such that a current flows through the wire 60. If the driving parts 50 are in operation when an impact is applied, the controller 201 stops the application of the voltage to each driving part 50. Accordingly, Lorentz forces are generated at the wire 60, so that excessive displacement of the vibration plate 20 can be suppressed without separately providing a stopper.

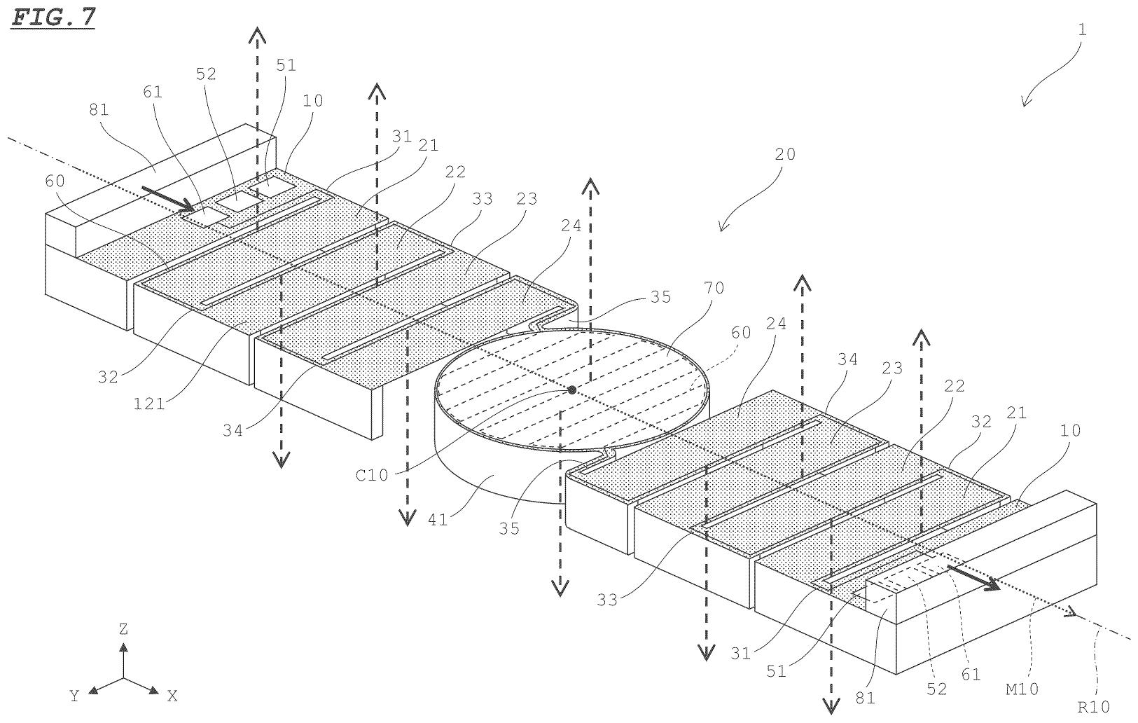

FIG. 7 is a perspective view for schematically illustrating suppression of excessive displacement of the vibration plate 20 by Lorentz forces.

The controller 201 controls the current supply part 205 such that when an impact is applied to the driving element 1, a current flows through the wire 60 from the electrode 61 on the X-axis negative side toward the electrode 61 on the X-axis positive side. Accordingly, Lorentz forces are generated in the Z-axis direction at the portions of the wire 60 that are orthogonal to the magnetic flux M10 in the X-axis positive direction, that is, the portions of the wire 60 that extend in the Y-axis direction at the neutral position in FIG. 7. In FIG. 7, the Lorentz forces generated for the wire 60 are shown by thick dashed arrows for convenience.

Specifically, a Lorentz force in the Z-axis negative direction is generated for the wire 60 on the vibration parts 22 and 24, and a Lorentz force in the Z-axis positive direction is generated for the wire 60 on the vibration parts 21 and 23. In addition, on the movable part 41, a Lorentz force in the Z-axis negative direction is generated for the portions of the wire 60 through which the current flows in the Y-axis negative direction, and a Lorentz force in the Z-axis positive direction is generated for the portions of the wire 60 through which the current flows in the Y-axis positive direction. That is, at the respective lines of the wire 60 extending in the Y-axis direction on the movable part 41, Lorentz forces in the Z-axis positive direction and the Z-axis negative direction are generated alternately for the respective lines.

Thus, when an impact is applied to the driving element 1, if a current is caused to flow through the wire 60 and Lorentz forces are generated in the Z-axis direction, displacement of the vibration plate 20 from the neutral position (position shown in FIG. 4) is suppressed.

The wire 60 is placed such that when a current is applied, the portions of the wire 60 through which the current flows in the Y-axis positive direction and the portions of the wire 60 through which the current flows in the Y-axis negative direction are balanced on the vibration plate 20. That is, the wire 60 is placed so as to be symmetrical about the rotation axis R10 in a plan view, and is also placed so as to be symmetrical about the center C10. Therefore, when a current flows through the wire 60, Lorentz forces are generated in a balanced manner in the Z-axis positive and negative directions.

Since the Lorentz forces are generated in a balanced manner in both Z-axis positive and negative directions as described above, even in a state where the vibration plate 20 is rotated from the neutral position, the vibration plate 20 is converged to the neutral position at which the Lorentz forces in both directions are balanced.

### Effects of Embodiment 1

According to Embodiment 1, the following effects are achieved.

Each driving part 50 is placed on the vibration plate 20 and vibrates the vibration plate 20. The movable part 41 is placed in the vibration plate 20 and is rotated by the vibration of the vibration plate 20. The wire 60 and the pair of permanent magnets 81 (displacement suppression part) suppress displacement of the vibration plate 20 from the neutral position by the forces generated by the action of the pair of permanent magnets 81 (magnets).

With this configuration, displacement of the vibration plate 20 from the neutral position is suppressed by the forces generated by the action of the magnets. Accordingly, when an impact is applied to the driving element 1, excessive displacement of the movable part 41 can be smoothly suppressed.

The wire 60 for braking is placed on the vibration plate 20. The pair of permanent magnets 81 (magnets) exert the magnetic flux M10 on the wire 60. When a current flows through the wire 60, the wire 60 and the pair of permanent magnets 81 (magnets) generate Lorentz forces that suppress displacement of the vibration plate 20 from the neutral position.

With this configuration, as shown in FIG. 7, when a current flows through the wire 60, Lorentz forces that suppress displacement of the vibration plate 20 from the neutral position are generated by the wire 60 and the permanent magnets 81. Accordingly, when an impact is applied to the driving element 1, excessive displacement of the movable part 41 can be smoothly suppressed by causing a current to flow through the wire 60 to apply Lorentz forces to the vibration plate 20.

Since excessive displacement of the vibration plate 20 can be suppressed by causing a current to flow through the wire 60, there is no need to provide a physical stopper for suppressing excessive displacement of the movable part 41. Accordingly, the driving element 1 can be configured in a simplified manner, and a situation in which the movable part 41 and a stopper are damaged due to the movable part 41 colliding with the stopper, can be avoided. In addition, since there is no need to provide a physical stopper, there is no need to assume a situation in which the movable part 41 and a stopper interfere with each other, so that the deflection angle of the movable part 41 can be set to be large. Moreover, by adjusting the magnitude of the current caused to flow through the wire 60, the magnitude of the Lorentz force can be adjusted in accordance with the magnitude of an impact, so that displacement of the movable part 41 can be properly suppressed.

As shown in FIG. 1 and FIG. 2, the wire 60 is placed along the driving parts 50. With this configuration, the Lorentz forces can be applied to the vibration plate 20 near the driving parts 50, so that excessive displacement of the vibration plate 20 near the driving parts 50 can be suppressed.

As shown in FIG. 3A, the wire 60 is placed so as to overlap the driving part 50. With this configuration, the areas of the driving parts 50 placed on the vibration parts 21 to 24 can be increased regardless of the placement position of the wire 60. That is, reduction of the areas of the driving parts 50 can be suppressed. Therefore, the driving forces of the driving parts 50 can be maintained high.

As shown in FIG. 2, the wire 60 is placed on the movable part 41. With this configuration, the Lorentz forces can be applied to the movable part 41, so that excessive displacement of the movable part 41 can be suppressed.

As shown in FIG. 2, the wire 60 is placed over substantially the entire range of the movable part 41. With this configuration, excessive displacement of the movable part 41 can be further effectively suppressed.

As shown in FIG. 7, the pair of permanent magnets 81, as magnets, exert the magnetic flux M10 on the wire 60. With this configuration, the magnets can be configured in a simplified manner.

As shown in FIG. 7, the mirror 70 is formed on the upper surface of the movable part 41, and the upper surface of the mirror 70 forms a reflection surface. With this configuration, light incident on the driving element 1 can be reflected in a desired direction in accordance with the rotation of the movable part 41.

As shown in FIG. 3A, each driving part 50 includes the piezoelectric layer 112 (piezoelectric body). With this configuration, by applying a voltage to the piezoelectric layer 112 to expand and contract the driving part 50, the vibration plate 20 can be expanded and contracted to rotate the movable part 41.

As shown in FIG. 6, the acceleration sensor 90 (sensor) detects an impact applied to the driving element 1, and the controller 201 controls the current supply part 205 based on detection of an impact by the acceleration sensor 90 (sensor). With this configuration, the controller 201 can control the current supply part 205 such that a current flows through the wire 60 when it is determined that an impact has been applied to the driving element 1, based on the detection signal of the acceleration sensor 90. Accordingly, Lorentz forces are generated in the driving element 1, so that excessive displacement of the movable part 41 due to the impact being applied can be suppressed.

As shown in FIG. 7, the vibration parts 21 to 24 and the driving parts 50 are placed on the X-axis negative side and the X-axis positive side of the movable part 41 with the movable part 41 interposed therebetween. Accordingly, the rotation angle of the movable part 41 can be made larger than in the case where the vibration parts 21 to 24 and the driving parts 50 are placed only on one side in the X-axis direction with respect to the movable part 41. In addition, the movable part 41 can be held stably, so that the driving element 1 can have high resistance to impacts from the outside.

### Embodiment 2

In Embodiment 1, the wire 60 is placed over substantially the entire range of the movable part 41. In contrast, in Embodiment 2, the wire 60 is placed only on portions of the movable part 41.

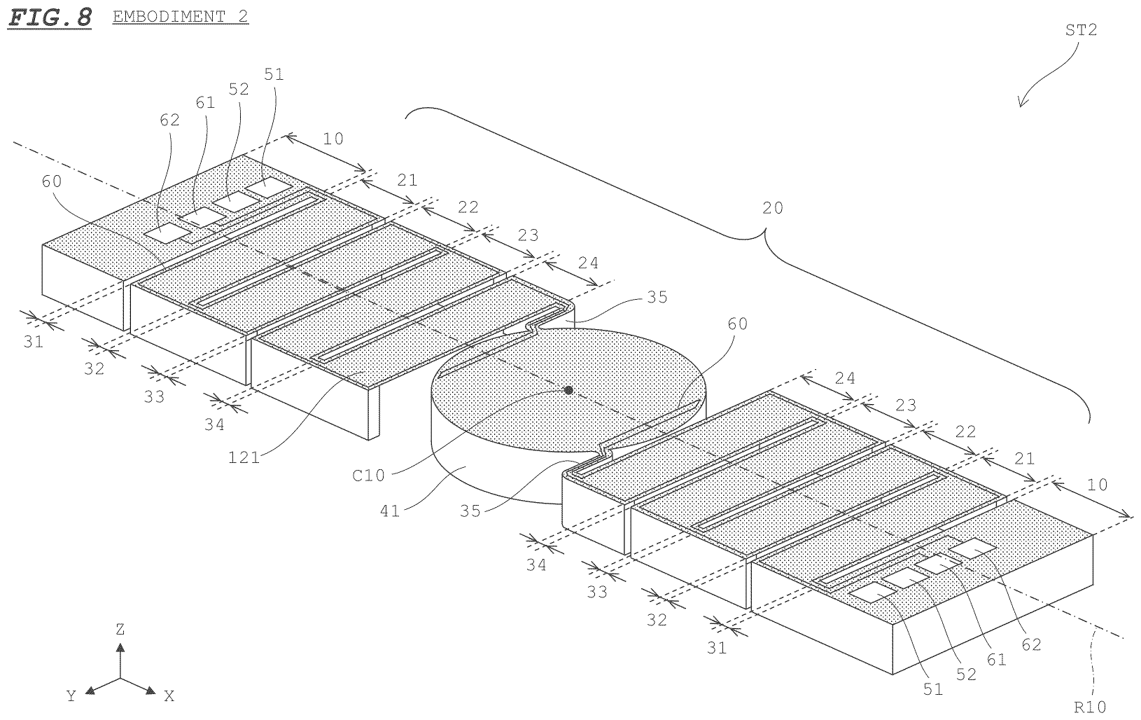

FIG. 8 is a perspective view schematically showing a configuration of a structure ST2 according to Embodiment 2.

In the structure ST2 of Embodiment 2, as compared to the structure ST2 of Embodiment 1 shown in FIG. 2, the placement of the wire 60 is changed, and a pair of electrodes 62 are placed on the fixation part 10.

On the X-axis negative side of the center C10, the electrodes 61 and 62 are placed on the fixation part 10, and a wire 60 connected to the electrode 61 passes through the vibration parts 21 to 24 and the connection parts 31 to 35, turns back near an end portion on the X-axis negative side of the movable part 41, passes through the vibration parts 21 to 24 and the connection parts 31 to 35 again, and is connected to the electrode 62. Similarly, on the X-axis positive side of the center C10, the electrodes 61 and 62 are placed on the fixation part 10, and a wire 60 connected to the electrode 61 passes through the vibration parts 21 to 24 and the connection parts 31 to 35, turns back near an end portion on the X-axis positive side of the movable part 41, passes through the vibration parts 21 to 24 and the connection parts 31 to 35 again, and is connected to the electrode 62. In this case as well, on the vibration parts 21 to 24 and the connection parts 31 to 35, the wires 60 are placed above the driving parts 50.

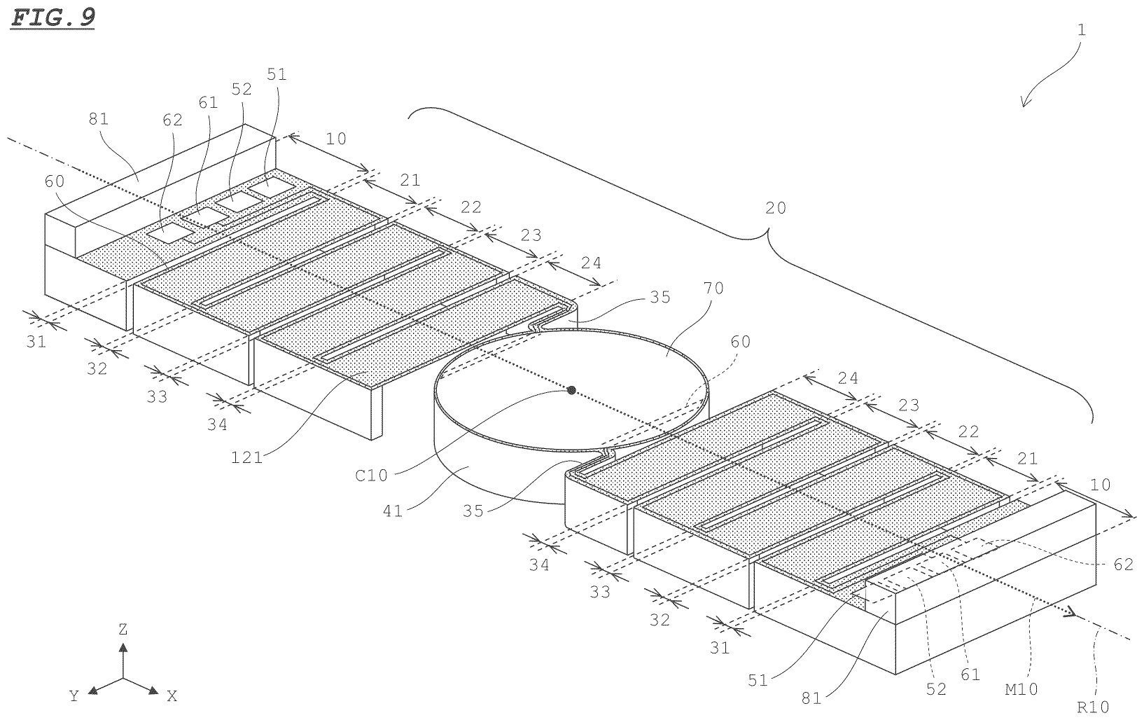

FIG. 9 is a perspective view schematically showing a configuration of a driving element 1 according to Embodiment 2.

After another insulating film is further formed on the upper surface side of the insulating layer 121 and the wires 60 on the movable part 41 shown in FIG. 8, a mirror 70 is formed on the upper surface of the other insulating film. In FIG. 9, the wires 60 located on the lower surface side of the mirror 70 are shown by dashed lines for convenience. In addition, as in Embodiment 1, a pair of permanent magnets 81 are installed on the upper surface side of the fixation part 10 located on the X-axis positive side and the X-axis negative side of the vibration plate 20, and the acceleration sensor 90 (see FIG. 5) is installed on the fixation part 10. Moreover, the two electrodes 61 and the two electrodes 62 are individually connected to the current supply part 205 (see FIG. 6). Thus, the driving element 1 of Embodiment 2 is completed.

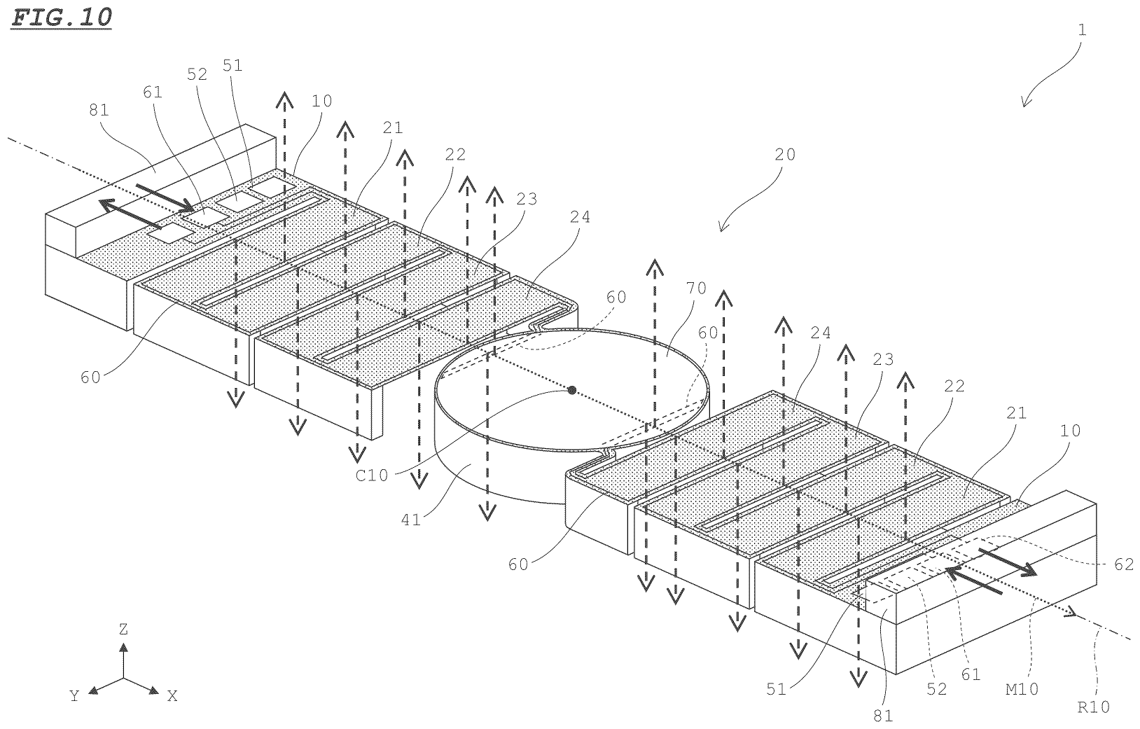

FIG. 10 is a perspective view for schematically illustrating suppression of excessive displacement of the vibration plate 20 by Lorentz forces according to Embodiment 2.

The controller 201 controls the current supply part 205 such that when an impact is applied to the driving element 1, a current flows through the wire 60 from the electrode 61 on the X-axis negative side toward the electrode 62 on the X-axis negative side and a current flows through the wire 60 from the electrode 61 on the X-axis positive side toward the electrode 62 on the X-axis positive side. Accordingly, Lorentz forces are generated in the Z-axis direction at the portions of the wires 60 that are orthogonal to the magnetic flux M10 in the X-axis positive direction, that is, the portions of the wires 60 that extend in the Y-axis direction at a neutral position in FIG. 10. In FIG. 10, the Lorentz forces generated for the wires 60 are shown by thick dashed arrows for convenience.

Specifically, Lorentz forces are generated in the Z-axis positive direction and the Z-axis negative direction for the portions of the two wires 60 that are placed on the vibration parts 21 to 24, respectively, and extend in the Y-axis direction. In addition, Lorentz forces are generated in the Z-axis positive direction and the Z-axis negative direction for the portions of the two wires 60 that are placed at the end portion on the X-axis negative side and the end portion on the X-axis positive side on the movable part 41, respectively, and extend in the Y-axis direction.

In Embodiment 2 as well, each wire 60 is placed such that when a current is applied, the portions of the wire 60 through which the current flows in the Y-axis positive direction and the portions of the wire 60 through which the current flows in the Y-axis negative direction are balanced on the vibration plate 20. Therefore, when a current flows through each wire 60, Lorentz forces are generated in a balanced manner in the Z-axis positive and negative directions. Since the Lorentz forces are generated in a balanced manner in both Z-axis positive and negative directions as described above, even in a state where the vibration plate 20 is rotated from the neutral position, the vibration plate 20 is converged to the neutral position at which the Lorentz forces in both directions are balanced.

If the driving parts 50 are in operation when an impact is applied, the controller 201 stops the application of the voltage to each driving part 50.

Thus, in Embodiment 2 as well, when an impact is applied to the driving element 1, excessive displacement of the movable part 41 can be smoothly suppressed by causing a current to flow through each wire 60 to apply Lorentz forces to the vibration plate 20. In addition, since Lorentz forces in the Z-axis positive direction and the Z-axis negative direction can be generated for each vibration part, excessive displacement of the movable part 41 can be reliably suppressed.

In Embodiment 2, no wire 60 is placed on most of the upper surface side of the movable part 41. Accordingly, formation of slight irregularities due to the wires 60 can be prevented when the mirror 70 is formed on the upper surface side of the movable part 41, so that an image can be accurately formed in a target area.

### Embodiment 3

In Embodiments 1 and 2, the pair of permanent magnets 81 are placed in order to generate the magnetic flux M10 in the X-axis positive direction, but the magnet for generating a magnetic flux may be a coil. In Embodiment 3, a coil 82 is placed instead of the pair of permanent magnets 81.

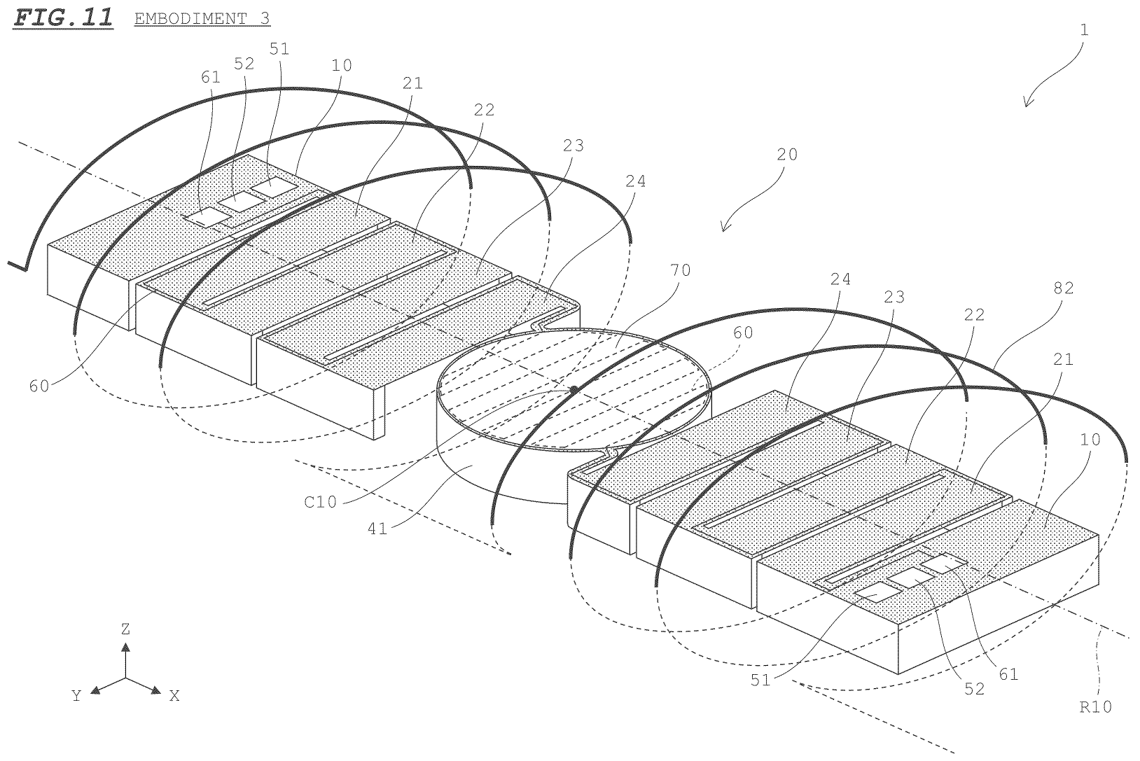

FIG. 11 is a perspective view schematically showing a configuration of a driving element 1 according to Embodiment 3.

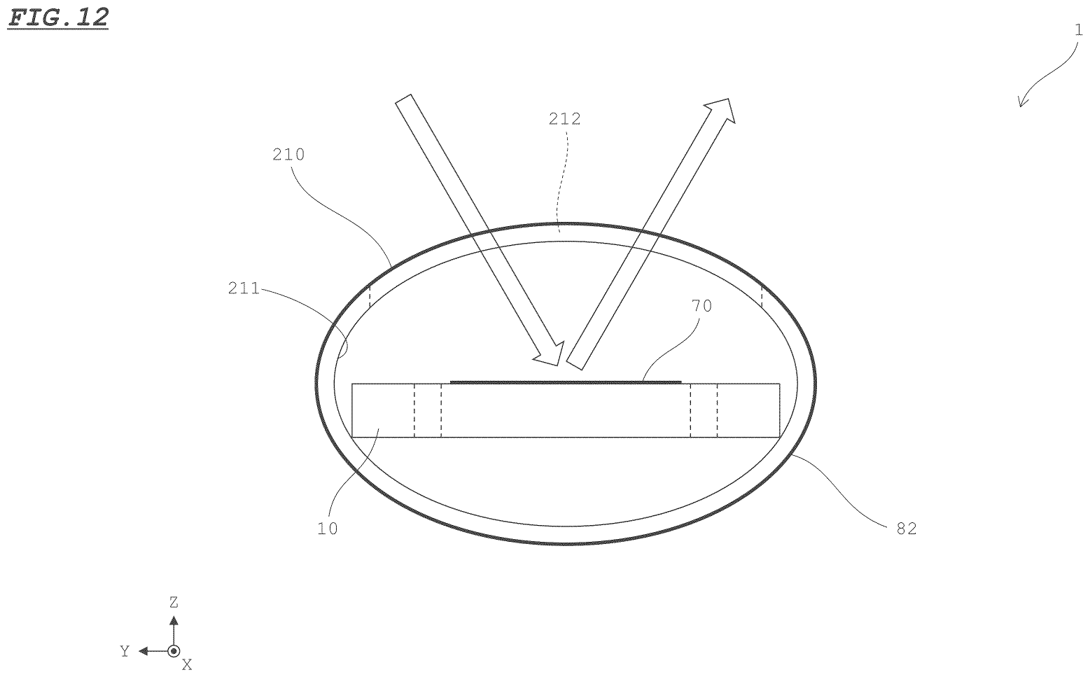

In the driving element 1 of Embodiment 3, as compared to the driving element 1 of Embodiment 1 shown in FIG. 4, the pair of permanent magnets 81 are omitted, and the coil 82 is added. The central axis of the coil 82 extends in the X-axis direction and coincides with the rotation axis R10. The coil 82 is wound around the rotation axis R10. In this case, the coil 82 is placed such that the coil 82 does not extend above the mirror 70 (the position of an opening 212 in FIG. 12). In FIG. 11, for convenience, portions of the coil 82 that are located higher than the upper surface of the mirror 70 are shown by thick slid lines, portions of the coil 82 that are located lower than the upper surface of the mirror 70 are shown by dashed lines. An end portion on the X-axis positive side and an end portion on the X-axis negative side of the coil 82 are connected to the current supply part 205 (see FIG. 6).

FIG. 12 is a side view schematically showing a configuration of a tubular member 210 in which the coil 82 is installed.

The tubular member 210 is a tubular member extending in the X-axis direction, and a hole 211 is formed therein so as to penetrate the tubular member 210 in the X-axis direction. The frame-shaped fixation part 10 of the driving element 1 is fixed inside the hole 211. The opening 212 is formed at the center position in the Y-axis direction of an end portion on the Z-axis positive side of the tubular member 210 so as to penetrate the tubular member 210 in the Z-axis direction. The mirror 70, of the driving element 1, which is placed inside the hole 211 is opened upward by the opening 212. The light from the light emitting part 203 is applied to the mirror 70 through the opening 212, and the light reflected by the mirror 70 is applied to a target area through the opening 212. The coil 82 is wound on the outer surface of the tubular member 210.

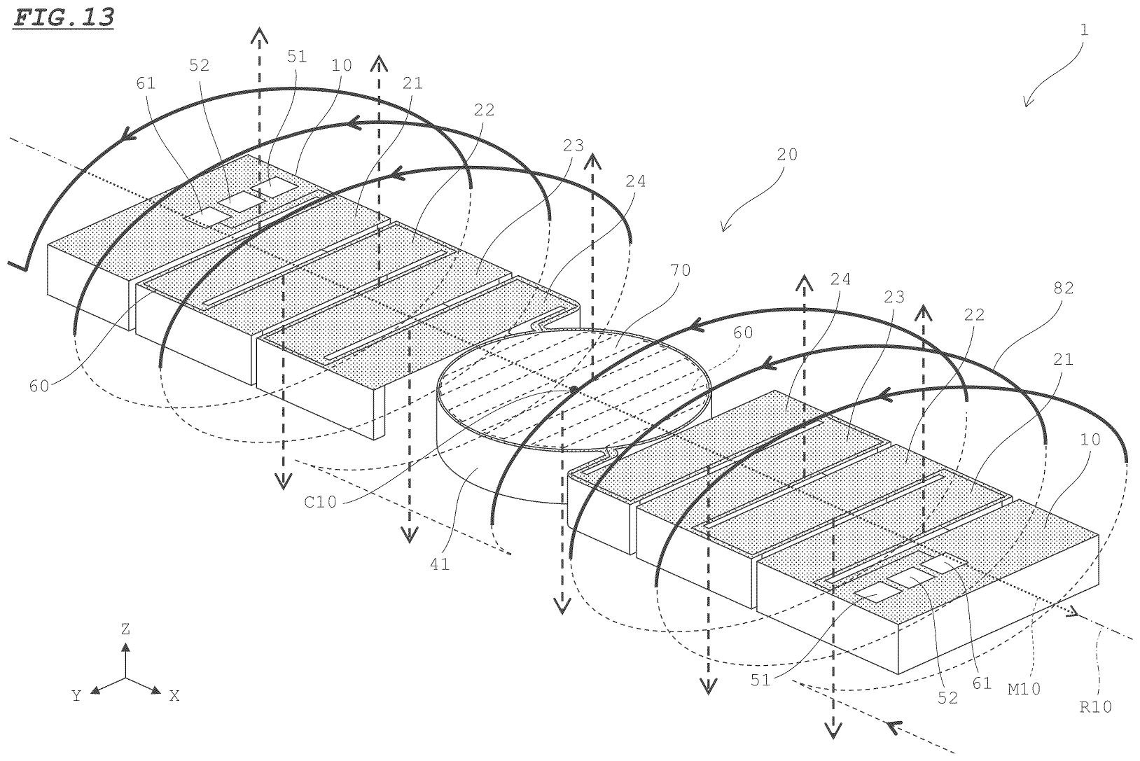

FIG. 13 is a perspective view for schematically illustrating suppression of excessive displacement of the vibration plate 20 by Lorentz forces according to Embodiment 3.

The controller 201 controls the current supply part 205 such that when an impact is applied to the driving element 1, a current flows through the coil 82 from the end portion on the X-axis positive side of the coil 82 to the end portion on the X-axis negative side of the coil 82. Accordingly, as in Embodiments 1 and 2, a magnetic flux M10 in the X-axis positive direction is generated. At the same time, the controller 201 controls the current supply part 205 such that a current flows through the wire 60 from the electrode 61 on the X-axis negative side toward the electrode 61 on the X-axis positive side. Accordingly, as in Embodiment 1, Lorentz forces are generated in the Z-axis direction at the portions of the wire 60 that are orthogonal to the magnetic flux M10 in the X-axis positive direction, that is, the portions of the wire 60 that extend in the Y-axis direction at a neutral position in FIG. 13. In FIG. 13, the Lorentz forces generated for the wire 60 are shown by thick dashed arrows for convenience.

If the driving parts 50 are in operation when an impact is applied, the controller 201 stops the application of the voltage to each driving part 50.

Thus, in Embodiment 3 as well, when an impact is applied to the driving element 1, excessive displacement of the movable part 41 can be smoothly suppressed by causing a current to flow through the coil 82 to generate the magnetic flux M10 and causing a current to flow through the wire 60 to apply Lorentz forces to the vibration plate 20.

In Embodiment 3, as shown in FIG. 13, the coil 82, as a magnet, exerts the magnetic flux M10 on the wire 60. With this configuration, by adjusting the magnitude of the current caused to flow through the coil 82, the magnitude of the magnetic flux M10 can be changed, thereby adjusting the magnitudes of the Lorentz forces. Thus, for example, displacement of the movable part 41 can be properly suppressed in accordance with the magnitude of an impact.

### Embodiment 4

In Embodiment 1, the magnetic flux M10 in the X-axis positive direction is generated by the pair of permanent magnets 81. In contrast, in Embodiment 4, a magnetic flux M20 in the Z-axis positive direction is generated by a coil 83.

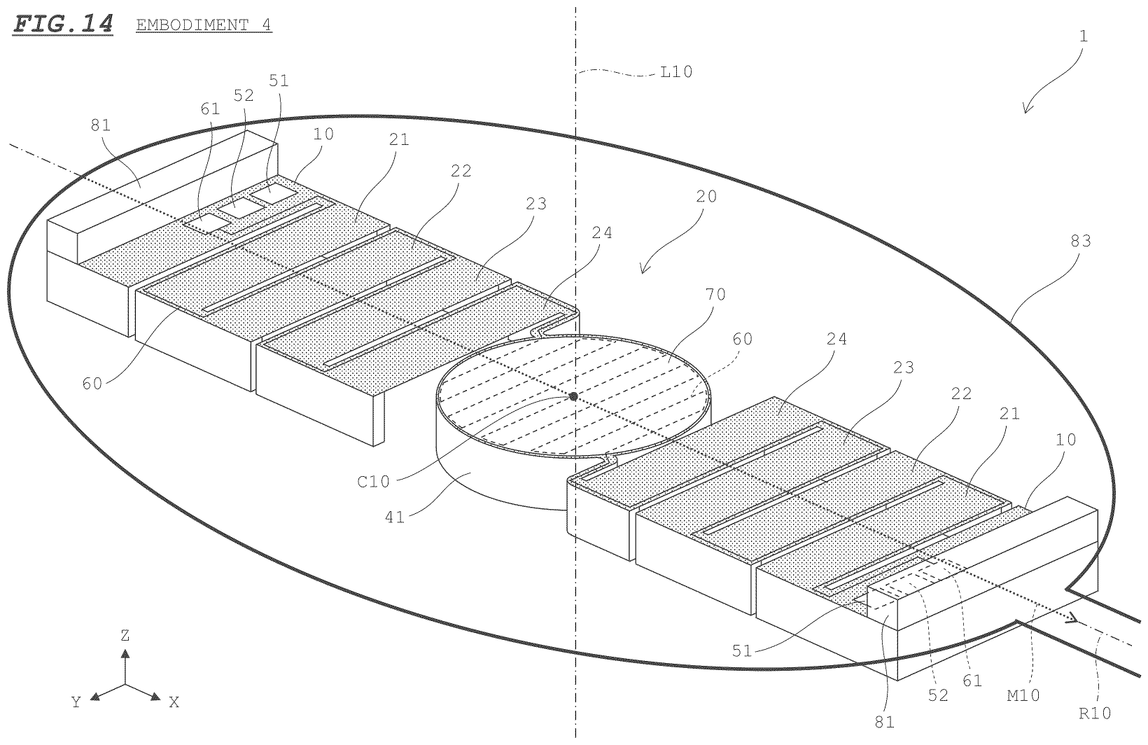

FIG. 14 is a perspective view schematically showing a configuration of a driving element 1 according to Embodiment 4.

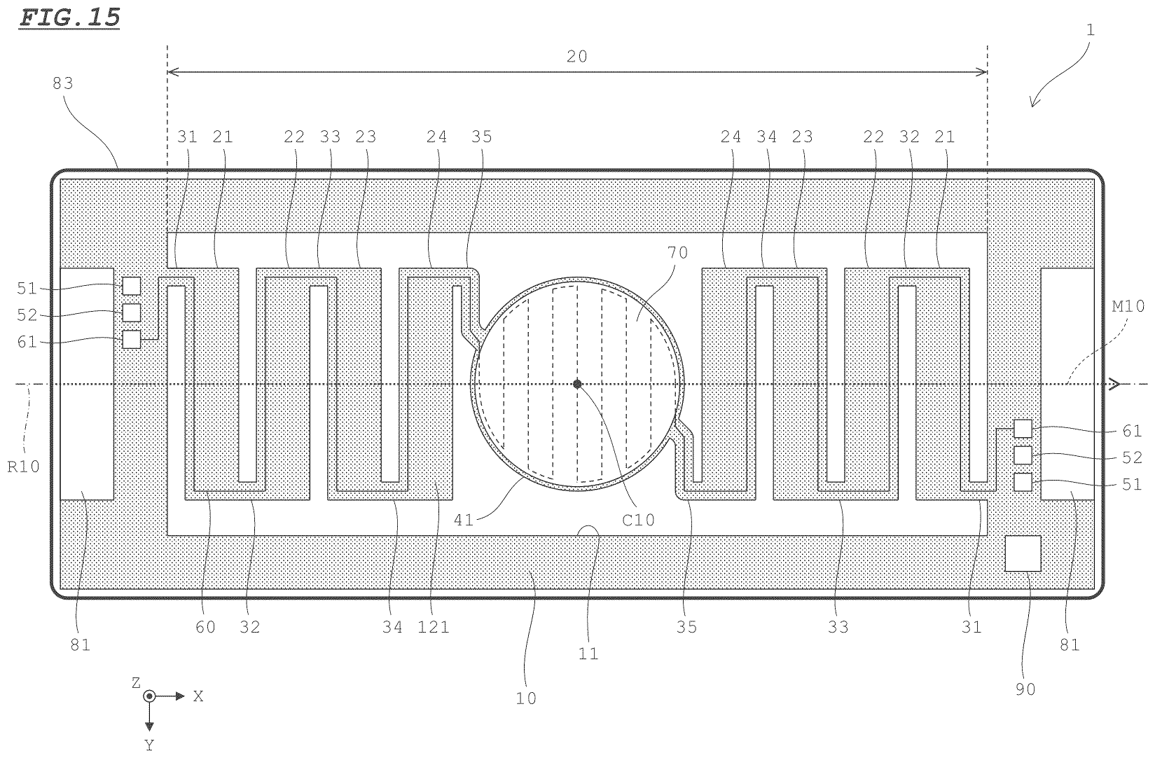

In the driving element 1 of Embodiment 4, as compared to the driving element 1 of Embodiment 1 shown in FIG. 4, the coil 83 is added. The central axis of the coil 83 extends in the Z-axis direction and coincides with a straight line L10 which passes through the center C10 and extends in the Z-axis direction. The coil 83 is wound around the straight line L10. Specifically, as shown in a plan view of FIG. 15, the coil 83 is wound on the outer side of the frame-shaped fixation part 10. Two end portions of the coil 83 are connected to the current supply part 205 (see FIG. 6).

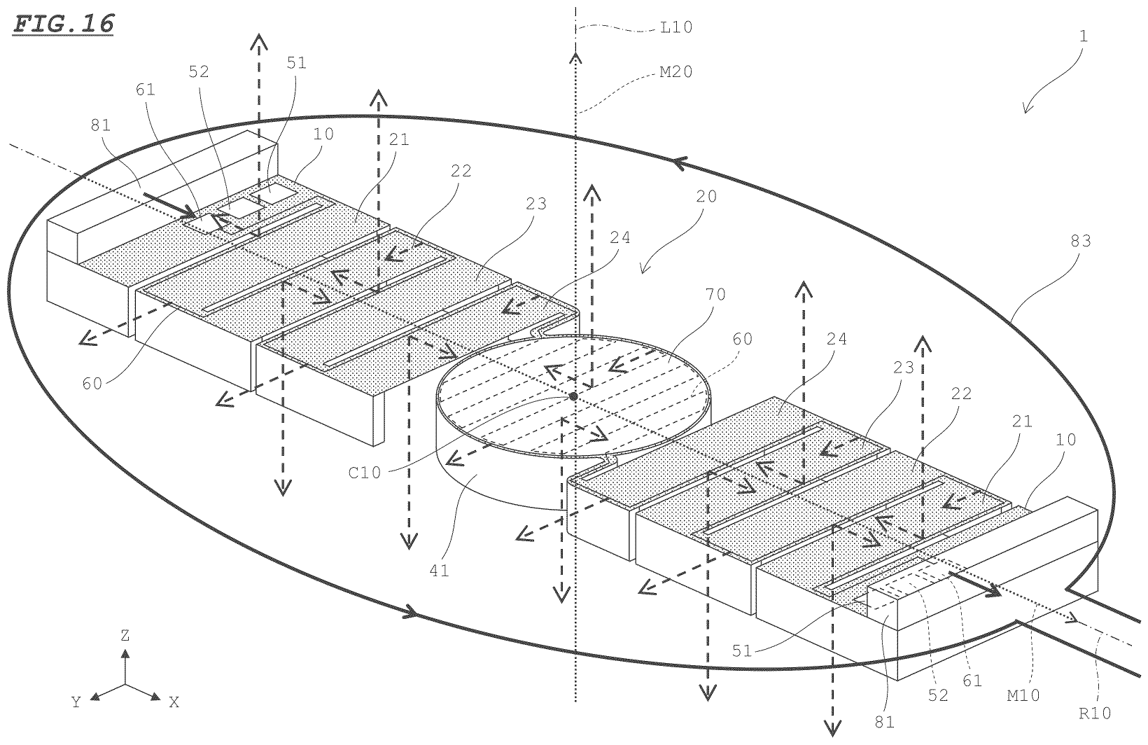

FIG. 16 is a perspective view for schematically illustrating suppression of excessive displacement of the vibration plate 20 by Lorentz forces according to Embodiment 4.

The controller 201 controls the current supply part 205 such that when an impact is applied to the driving element 1, a current flows through the coil 83 in a clockwise direction viewed in the Z-axis positive direction. Accordingly, a magnetic flux M20 in the Z-axis positive direction is generated. At the same time, the controller 201 controls the current supply part 205 such that a current flows through the wire 60 from the electrode 61 on the X-axis negative side toward the electrode 61 on the X-axis positive side.

Accordingly, as in Embodiment 1, Lorentz forces are generated in the Z-axis direction at the portions of the wire 60 that are orthogonal to the magnetic flux M10 in the X-axis positive direction, that is, the portions of the wire 60 that extend in the Y-axis direction at a neutral position in FIG. 16.

Furthermore, in Embodiment 4, Lorentz forces are generated in the X-axis direction or the Y-axis direction at the portions of the wire 60 that are orthogonal to the magnetic flux M20 in the Z-axis positive direction, that is, the portions of the wire 60 that extend in the X-axis direction or the Y-axis direction at the neutral position in FIG. 16. Specifically, Lorentz forces in the X-axis negative direction or the X-axis positive direction are generated at the portions of the wire 60 that extend in the Y-axis direction at the vibration parts 21 to 24 and the movable part 41. In addition, Lorentz forces in the Y-axis positive direction are generated at the portions of the wire 60 that extend in the X-axis direction at the vibration parts 21 to 24 and the movable part 41. In FIG. 16, the Lorentz forces generated for the wire 60 are shown by thick dashed arrows for convenience.

The wire 60 is placed such that when a current is applied, the portions of the wire 60 through which the current flows in the Y-axis positive direction and the portions of the wire 60 through which the current flows in the Y-axis negative direction are balanced on the vibration plate 20. Therefore, when a current flows through the wire 60, Lorentz forces are generated in a balanced manner in the Z-axis positive and negative directions, and Lorentz forces are generated in a balanced manner in the X-axis positive and negative directions. Thus, since the Lorentz forces are generated in a balanced manner in both Z-axis positive and negative directions and in both X-axis positive and negative directions, even in a state where the vibration plate 20 is displaced from the neutral position, the vibration plate 20 is converged to the neutral position at which the Lorentz forces in both directions are balanced.

If the driving parts 50 are in operation when an impact is applied, the controller 201 stops the application of the voltage to each driving part 50.

Thus, in Embodiment 4 as well, when an impact is applied to the driving element 1, a current can be caused to flow through the wire 60 to apply Lorentz forces in the Z-axis direction to the vibration plate 20. In addition, at the same time, a current can be caused to flow through the coil 83 to generate the magnetic flux M20 and apply Lorentz forces in the X-axis direction and the Y-axis direction to the vibration plate 20. Accordingly, excessive displacement of the movable part 41 can be suppressed more smoothly as compared to Embodiment 1.

In addition, in Embodiment 4 as well, as shown in FIG. 16, the coil 83, as a magnet, exerts the magnetic flux M20 on the wire 60. With this configuration, by adjusting the magnitude of the current caused to flow through the coil 83, the magnitude of the magnetic flux M20 can be changed, thereby adjusting the magnitudes of the Lorentz forces. Thus, for example, displacement of the movable part 41 can be properly suppressed in accordance with the magnitude of an impact.

### Embodiment 5

In Embodiment 4, the coil 83 is provided so as to surround the vibration plate 20 in a plan view in order to generate the magnetic flux M20 in the Z-axis direction. In contrast, in Embodiment 5, three coils 84 are placed below the vibration plate 20 in order to generate magnetic fluxes M31 to M33 in the Z-axis direction.

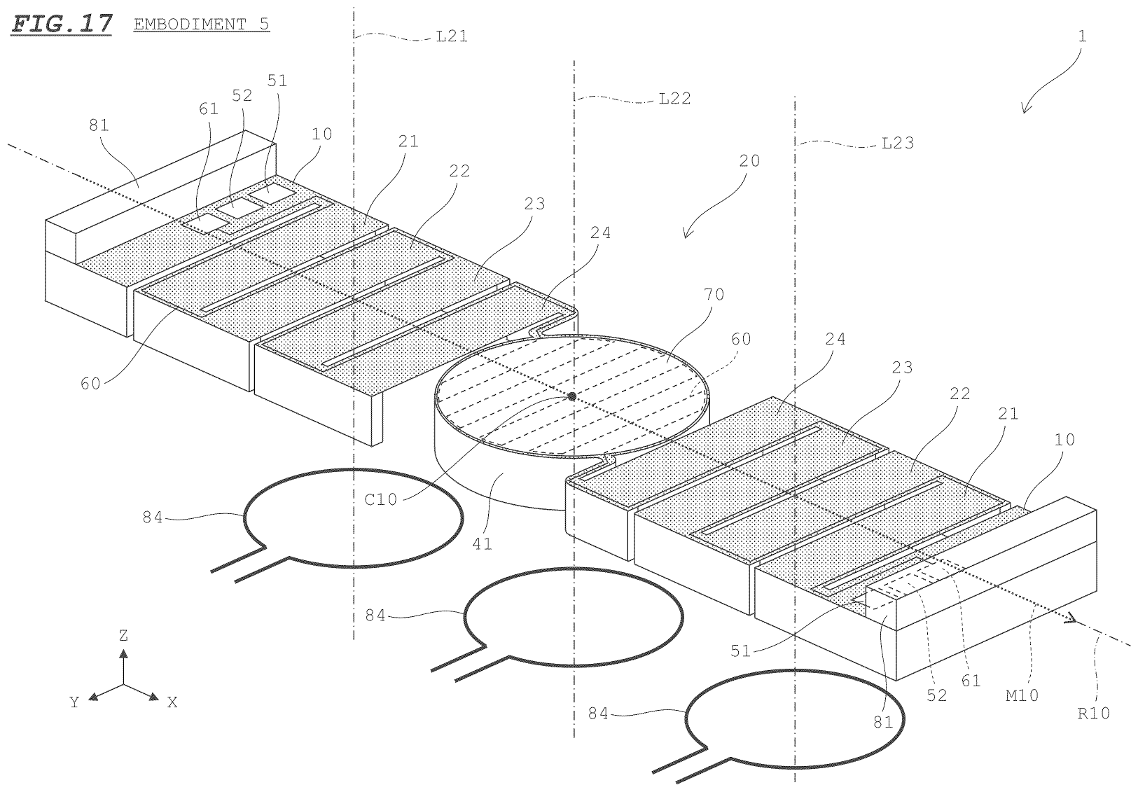

FIG. 17 is a perspective view schematically showing a configuration of a driving element 1 according to Embodiment 5.

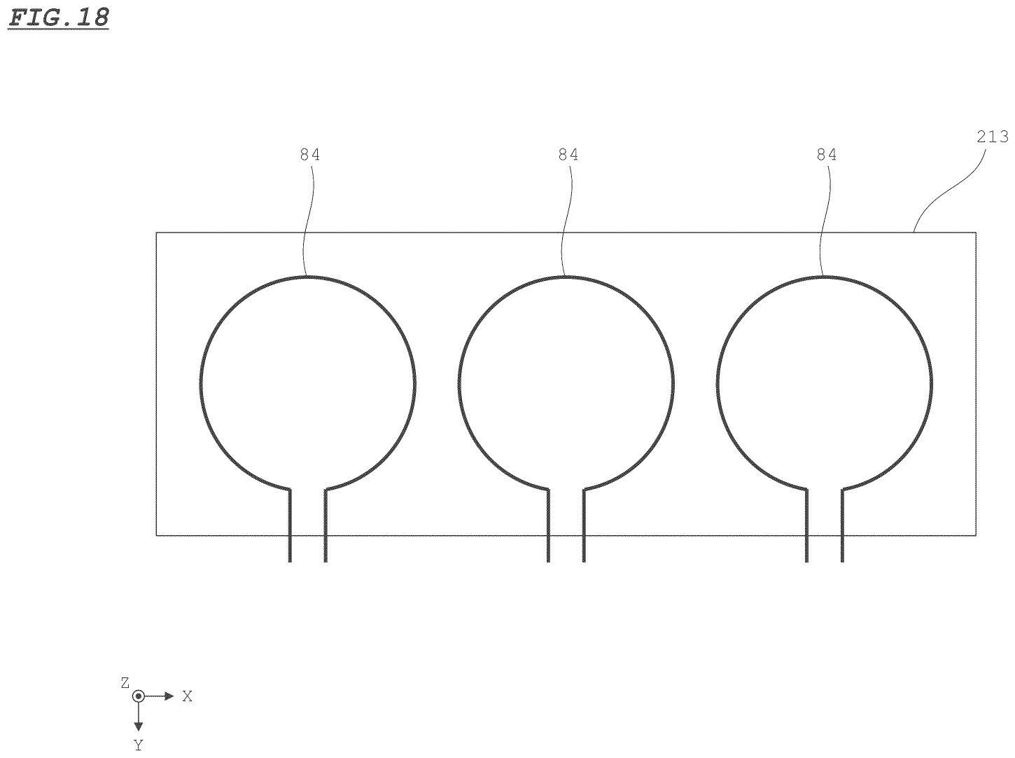

In the driving element 1 of Embodiment 5, as compared to the driving element 1 of Embodiment 4 shown in FIG. 14, the coil 83 is omitted, and the three coils 84 are added. The central axes of the three coils 84 coincide with straight lines L21 to L23 extending in the Z-axis direction, respectively. The straight line L22 corresponding to the central coil 84 passes through the center C10. The three coils 84 are wound around the straight lines L21 to L23, respectively. Specifically, as shown in a plan view of FIG. 18, the three coils 84 are wound in a circular shape on a substrate 213 parallel to the X-Y plane. Two end portions of each coil 84 are connected to the current supply part 205 (see FIG. 6).

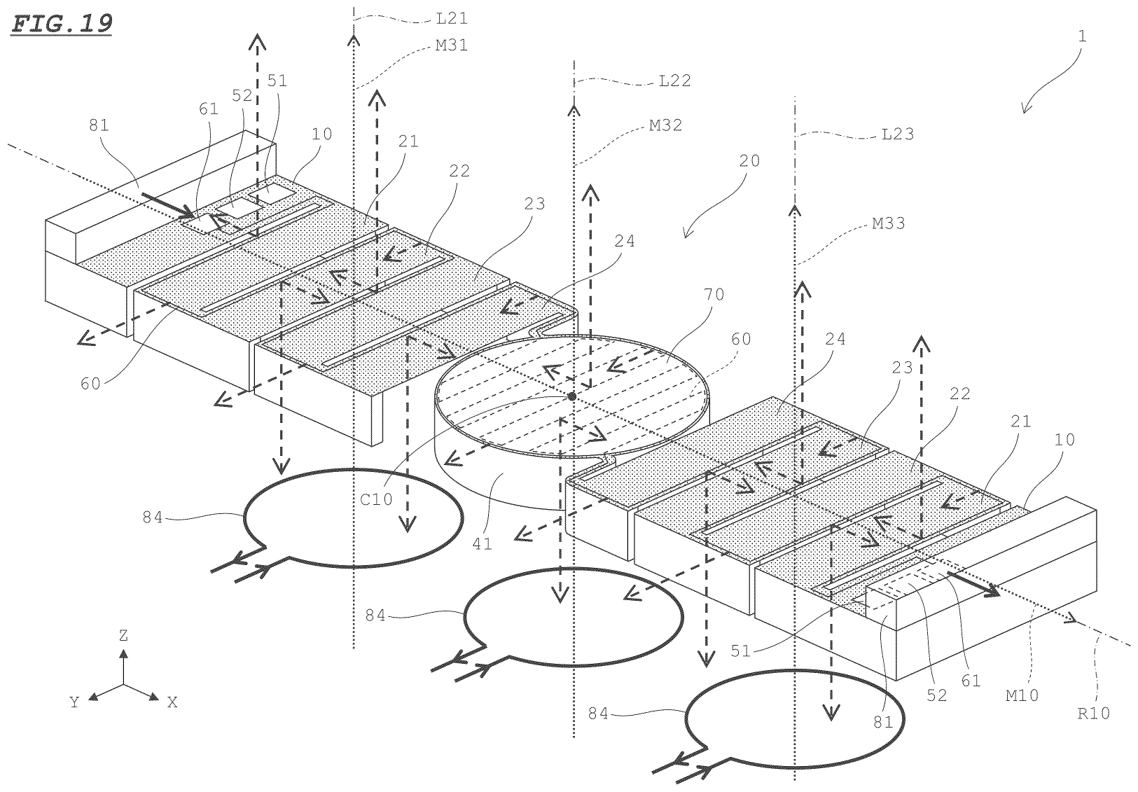

FIG. 19 is a perspective view for schematically illustrating suppression of excessive displacement of the vibration plate 20 by Lorentz forces according to Embodiment 5.

The controller 201 controls the current supply part 205 such that when an impact is applied to the driving element 1, currents flow through the three coils 84 in a clockwise direction viewed in the Z-axis positive direction. Accordingly, three magnetic fluxes M31 to M33 in the Z-axis positive direction are generated. At the same time, the controller 201 controls the current supply part 205 such that a current flows through the wire 60 from the electrode 61 on the X-axis negative side toward the electrode 61 on the X-axis positive side.

Accordingly, as in Embodiment 1, Lorentz forces are generated in the Z-axis direction at the portions of the wire 60 that are orthogonal to the magnetic flux M10 in the X-axis positive direction, that is, the portions of the wire 60 that extend in the Y-axis direction at a neutral position in FIG. 19. In addition, as in Embodiment 4, Lorentz forces are generated in the X-axis direction or the Y-axis direction at the portions of the wire 60 that are orthogonal to the magnetic fluxes M31 to M33 in the Z-axis positive direction, that is, the portions of the wire 60 that extend in the X-axis direction or the Y-axis direction at the neutral position in FIG. 19. In FIG. 19, the Lorentz forces generated for the wire 60 are shown by thick dashed arrows for convenience.

If the driving parts 50 are in operation when an impact is applied, the controller 201 stops the application of the voltage to each driving part 50.

Thus, in Embodiment 5 as well, when an impact is applied to the driving element 1, currents can be caused to flow through the wire 60 and the three coils 84 to apply Lorentz forces in the Z-axis direction, the X-axis direction, and the Y-axis direction to the vibration plate 20. Accordingly, as in Embodiment 4, excessive displacement of the movable part 41 can be smoothly suppressed.

In addition, in Embodiment 5 as well, as shown in FIG. 19, the three coils 84, as magnets, exert the magnetic fluxes M31 to M33 on the wire 60. Accordingly, by adjusting the magnitude of the current caused to flow through each coil 84, the magnitudes of the magnetic fluxes M31 to M33 can be changed, thereby adjusting the magnitudes of the Lorentz forces. Thus, for example, displacement of the movable part 41 can be properly suppressed in accordance with the magnitude of an impact. In addition, since different currents can be caused to flow through the three coils 84, respectively, displacement of a portion of the vibration plate 20 for which fluctuations are desired to be suppressed can be suppressed effectively.

### Embodiment 6

In Embodiment 4, the pair of permanent magnets 81 are provided in order to generate the magnetic flux M10 extending in the X-axis direction. In contrast, in Embodiment 6, a coil 82 which is the same as in Embodiment 3 is provided in order to generate a magnetic flux M10 extending in the X-axis direction.

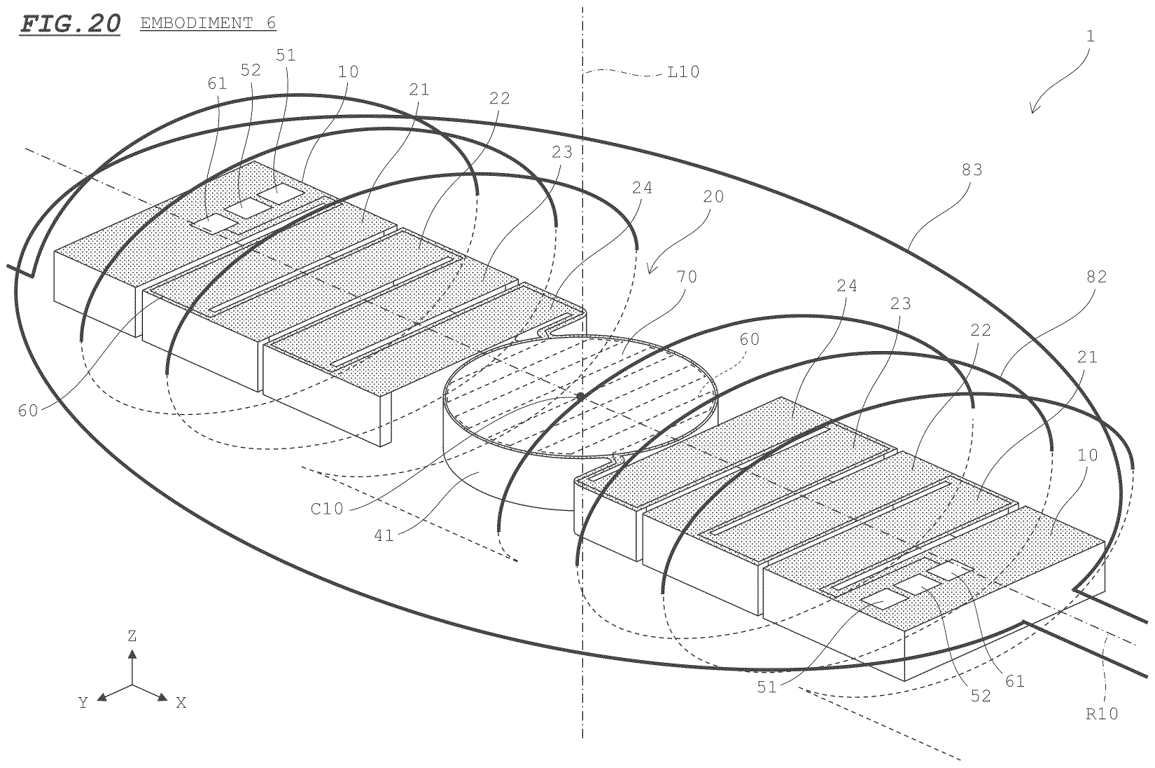

FIG. 20 is a perspective view schematically showing a configuration of a driving element 1 according to Embodiment 6.

In the driving element 1 of Embodiment 6, as compared to the driving element 1 of Embodiment 4 shown in FIG. 14, the pair of permanent magnets 81 are omitted, and the coil 82 which is the same as in Embodiment 3 shown in FIG. 11 is added. Two end portions of the coil 82 and two end portions of the coil 83 are connected to the current supply part 205 (see FIG. 6).

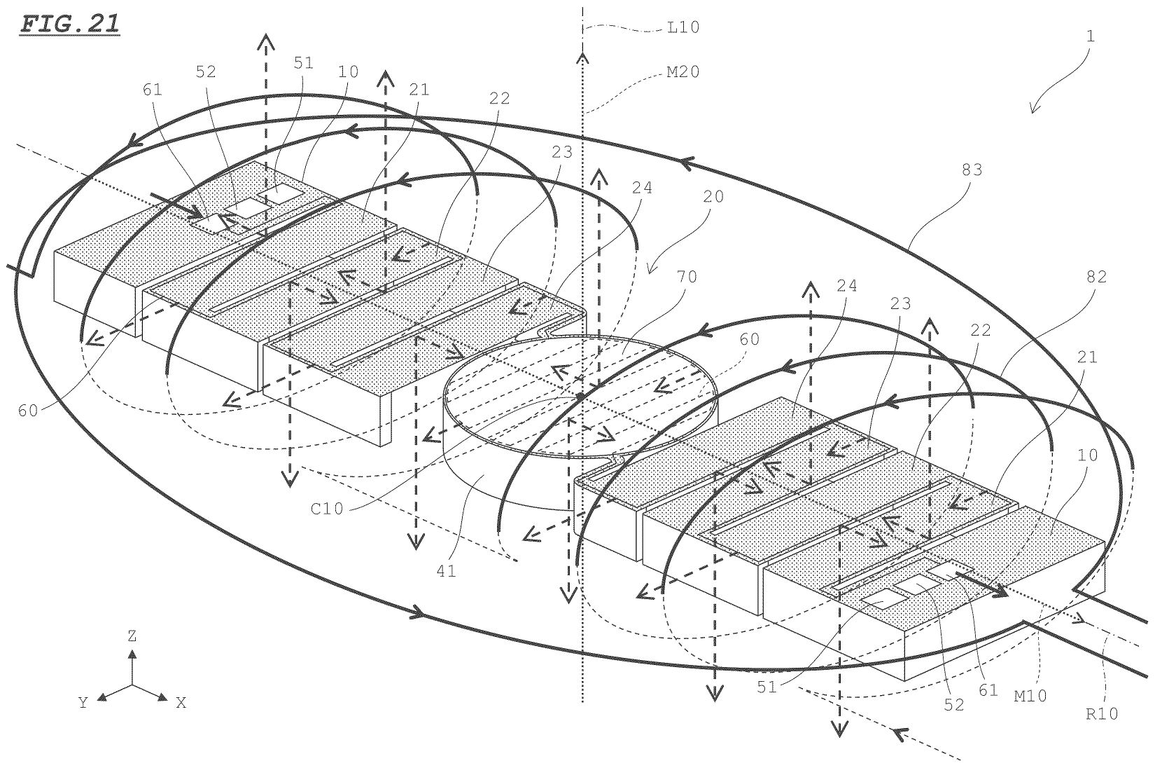

FIG. 21 is a perspective view for schematically illustrating suppression of excessive displacement of the vibration plate 20 by Lorentz forces according to Embodiment 6.

The controller 201 controls the current supply part 205 such that when an impact is applied to the driving element 1, a current flows through the coil 82 in a clockwise direction viewed in the X-axis positive direction and a current flows through the coil 83 in the clockwise direction viewed in the Z-axis positive direction. Accordingly, a magnetic flux M10 in the X-axis positive direction and a magnetic flux M20 in the Z-axis positive direction are generated. At the same time, the controller 201 controls the current supply part 205 such that a current flows through the wire 60 from the electrode 61 on the X-axis negative side toward the electrode 61 on the X-axis positive side.

Accordingly, as in Embodiment 4, Lorentz forces are generated in the Z-axis direction at the portions of the wire 60 that are orthogonal to the magnetic flux M10 in the X-axis positive direction, that is, the portions of the wire 60 that extend in the Y-axis direction at a neutral position in FIG. 21. In addition, Lorentz forces are generated in the X-axis direction or the Y-axis direction at the portions of the wire 60 that are orthogonal to the magnetic flux M20 in the Z-axis positive direction, that is, the portions of the wire 60 that extend in the X-axis direction or the Y-axis direction at the neutral position in FIG. 21. In FIG. 21, the Lorentz forces generated for the wire 60 are shown by thick dashed arrows for convenience.

If the driving parts 50 are in operation when an impact is applied, the controller 201 stops the application of the voltage to each driving part 50.

Thus, in Embodiment 6 as well, as in Embodiment 4, excessive displacement of the movable part 41 can be smoothly suppressed. In addition, the coils 82 and 83, as magnets, exert the magnetic fluxes M10 and M20 on the wire 60. Accordingly, by adjusting the magnitudes of the currents caused to flow through the coils 82 and 83, the magnitudes of the magnetic fluxes M10 and M20 can be changed, thereby adjusting the magnitudes of the Lorentz forces. Thus, for example, displacement of the movable part 41 can be properly suppressed in accordance with the magnitude of an impact.

### Embodiment 7

In Embodiment 5, the pair of permanent magnets 81 are provided in order to generate the magnetic flux M10 extending in the X-axis direction. In contrast, in Embodiment 7, a coil 82 which is the same as in Embodiment 3 is provided in order to generate a magnetic flux M10 extending in the X-axis direction.

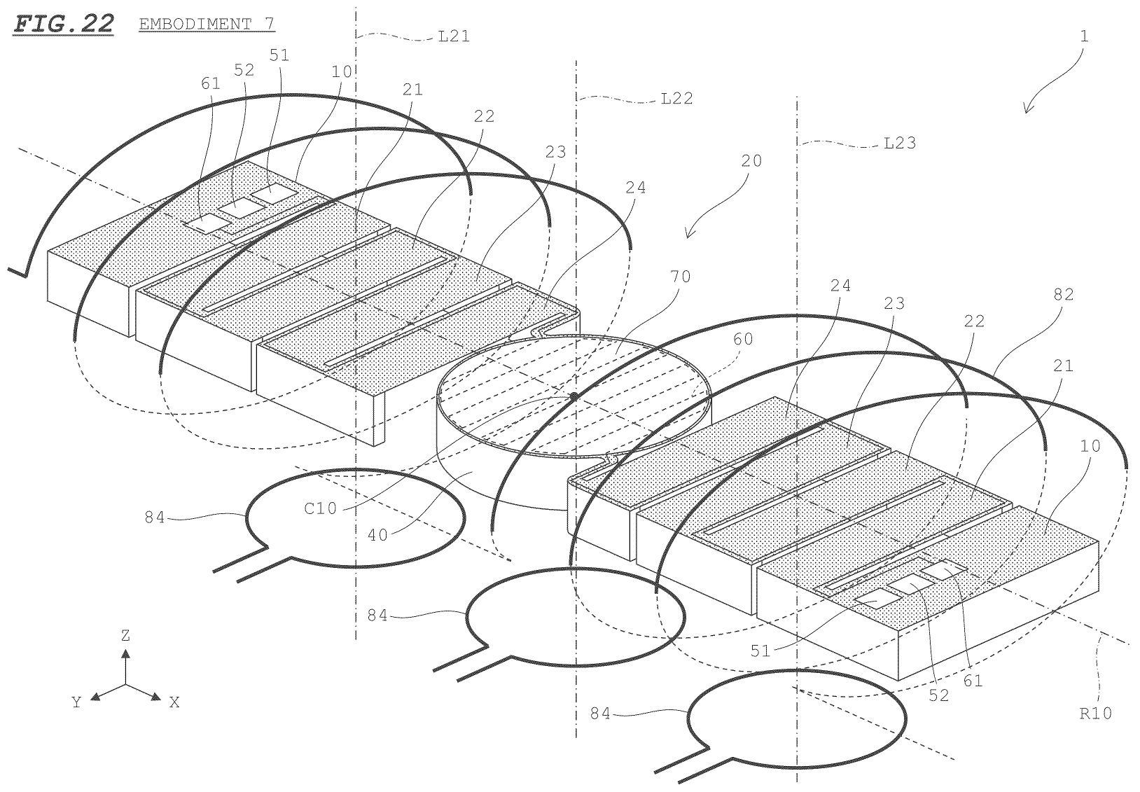

FIG. 22 is a perspective view schematically showing a configuration of a driving element 1 according to Embodiment 7.

In the driving element 1 of Embodiment 7, as compared to the driving element 1 of Embodiment 5 shown in FIG. 17, the pair of permanent magnets 81 are omitted, and the coil 82 which is the same as in Embodiment 3 shown in FIG. 11 is added. Two end portions of the coil 82 and two end portions of each coil 84 are connected to the current supply part 205 (see FIG. 6).

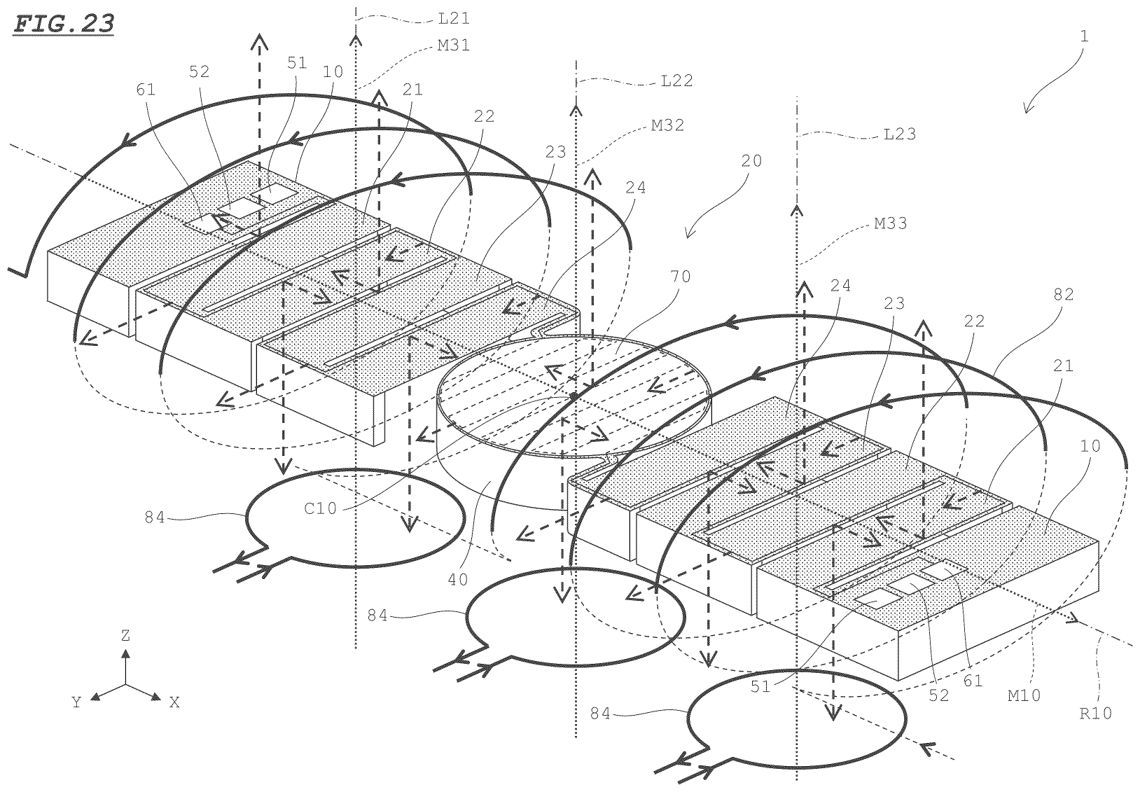

FIG. 23 is a perspective view for schematically illustrating suppression of excessive displacement of the vibration plate 20 by Lorentz forces according to Embodiment 7.

The controller 201 controls the current supply part 205 such that when an impact is applied to the driving element 1, a current flows through the coil 82 in a clockwise direction viewed in the X-axis positive direction and currents flow through the three coils 84 in the clockwise direction viewed in the Z-axis positive direction. Accordingly, a magnetic flux M10 in the X-axis positive direction and three magnetic fluxes M31 to M33 in the Z-axis positive direction are generated. At the same time, the controller 201 controls the current supply part 205 such that a current flows through the wire 60 from the electrode 61 on the X-axis negative side toward the electrode 61 on the X-axis positive side.

Accordingly, as in Embodiment 5, Lorentz forces are generated in the Z-axis direction at the portions of the wire 60 that are orthogonal to the magnetic flux M10 in the X-axis positive direction, that is, the portions of the wire 60 that extend in the Y-axis direction at a neutral position in FIG. 23. In addition, Lorentz forces are generated in the X-axis direction or the Y-axis direction at the portions of the wire 60 that are orthogonal to the magnetic fluxes M31 to M33 in the Z-axis positive direction, that is, the portions of the wire 60 that extend in the X-axis direction or the Y-axis direction at the neutral position in FIG. 23. In FIG. 23, the Lorentz forces generated for the wire 60 are shown by thick dashed arrows for convenience.

If the driving parts 50 are in operation when an impact is applied, the controller 201 stops the application of the voltage to each driving part 50.

Thus, in Embodiment 7 as well, as in Embodiment 5, excessive displacement of the movable part 41 can be smoothly suppressed. In addition, the coils 82 and 84, as magnets, exert the magnetic fluxes M10 and M31 to M33 on the wire 60. Accordingly, by adjusting the magnitudes of the currents caused to flow through the coils 82 and 84, the magnitudes of the magnetic fluxes M10 and M31 to M33 can be changed, thereby adjusting the magnitudes of the Lorentz forces. Thus, for example, displacement of the movable part 41 can be properly suppressed in accordance with the magnitude of an impact.

### Embodiment 8

In Embodiments 1 to 7, the vibration plate 20 has a meander shape. In contrast, in Embodiment 8, a vibration plate 220 has a tuning fork shape.

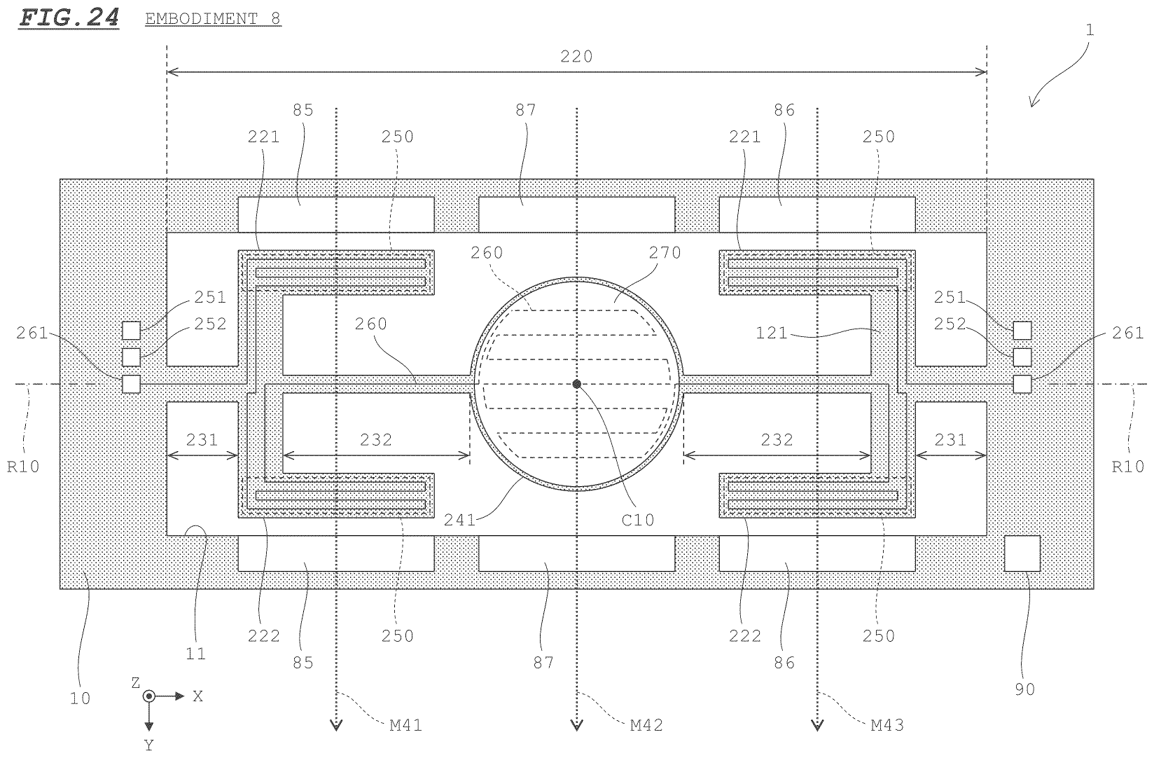

FIG. 24 is a plan view schematically showing a configuration of a driving element 1 according to Embodiment 8.

The driving element 1 of Embodiment 8 is also configured to be symmetrical in the X-axis direction and the Y-axis direction about a center C10. In FIG. 24, the same components as in Embodiment 1 are designated by the same reference characters as in Embodiment 1. In Embodiment 8, components having the same functions as in Embodiment 1 are composed of the same materials as in Embodiment 1. Hereinafter, the differences from Embodiment 1 will be described.

The vibration plate 220 is located inside the frame shape of the fixation part 10 in a plan view, and an end portion on the X-axis positive side and an end portion on the X-axis negative side of the vibration plate 220 are supported by the fixation part 10. The vibration plate 220 includes a movable part 241 at the position of the center C10. The movable part 241 rotates about a rotation axis R10 which passes through the center C10 and extends in the X-axis direction.

The vibration plate 220 has a tuning fork shape. The vibration plate 220 includes vibration parts 221 and 222 and connection parts 231 and 232 on each of the X-axis positive side and the X-axis negative side of the movable part 241.

The vibration parts 221 and 222 each have an L-shape. The vibration parts 221 and 222 each have a shape extending in the X-axis direction near a distal end thereof and have a shape extending in the Y-axis direction near the connection with the connection part 231 or 232. Portions, of the vibration parts 221 and 222, around the rotation axis R10 are connected to the fixation part 10 via the connection part 231, and are connected to the movable part 241 via the connection part 232. The vibration parts 221 are placed on the Y-axis negative side of the rotation axis R10, and the vibration parts 222 are placed on the Y-axis positive side of the rotation axis R10. The connection parts 231 and 232 extend in the X-axis direction along the rotation axis R10.

A driving part 250 is placed on each of the upper surfaces of the vibration parts 221 and 222 on the X-axis negative side of the movable part 241, and a driving part 250 is placed on each of the upper surfaces of the vibration parts 221 and 222 on the X-axis positive side of the movable part 241. Each driving part 250 has the same lamination structure as each driving part 50 of Embodiment 1. On the X-axis negative side of the movable part 241, the driving part 250 placed on the vibration part 221 is connected to an electrode 251, and the driving part 250 placed on the vibration part 222 is connected to an electrode 252. Similarly, on the X-axis positive side of the movable part 241, the driving part 250 placed on the vibration part 221 is connected to an electrode 251, and the driving part 250 placed on the vibration part 222 is connected to an electrode 252.

After the driving parts 250 are formed, an insulating layer 121 is formed on the upper surfaces of the fixation part 10 and the vibration plate 220, and a wire 260 is formed on the upper surface of the insulating layer 121. In FIG. 24, the insulating layer 121 is illustrated by hatching.

An end portion on the X-axis negative side and an end portion on the X-axis positive side of the wire 260 are connected to electrodes 261 at the fixation part 10. The wire 260 extends from one electrode 261 to the other electrode 261, and is formed on the upper surface (surface on the Z-axis positive side) of the insulating layer 121 on the vibration parts 221 and 222, the connection parts 231 and 232, and the movable part 241. The wire 260 is placed so as to extend back and forth multiple times in the X-axis direction on the vibration parts 221 and 222 and the movable part 241.

After another insulating film is further formed on the upper surface side of the insulating layer 121 and the wire 260 placed on the movable part 241, a mirror 270 is formed on the upper surface of the other insulating film. In FIG. 24, the wire 260 located on the lower surface side of the mirror 270 is shown by a dashed line for convenience.

A pair of permanent magnets 85 are installed on the fixation part 10 on the Y-axis positive side and the Y-axis negative side of the vibration parts 221 and 222 on the X-axis negative side, a pair of permanent magnets 86 are installed on the fixation part 10 on the Y-axis positive side and the Y-axis negative side of the vibration parts 221 and 222 on the X-axis positive side, and a pair of permanent magnets 87 are installed on the fixation part 10 on the Y-axis positive side and the Y-axis negative side of the mirror 270. The pairs of permanent magnets 85 to 87 generate magnetic fluxes M41 to M43, respectively, and are placed such that the directions of the magnetic fluxes M41 to M43 are the Y-axis positive direction.

As in Embodiment 1, an acceleration sensor 90 is installed on the fixation part 10.

In rotating the mirror 270, drive signals having the same phase are applied to the two driving parts 250 connected to the two electrodes 251 such that the two vibration parts 221 vibrate in the same direction in the Z-axis direction. In addition, drive signals having the same phase are applied to the two driving parts 250 connected to the two electrodes 252 such that the two vibration parts 222 vibrate in the same direction in the Z-axis direction. Moreover, drive signals having opposite phases are applied to the two driving parts 250 connected to the electrodes 251 and the two driving parts 250 connected to the electrodes 252 such that the vibration parts 221 and the vibration parts 222 vibrate in opposite directions in the Z-axis direction. Accordingly, the movable part 241 and the mirror 270 rotate about the rotation axis R10, so that the direction of light incident on the mirror 270 is changed in accordance with the rotation angle of the mirror 270.

The controller 201 controls the current supply part 205 such that when an impact is applied to the driving element 1, a current flows through the wire 60 from the electrode 61 on the X-axis negative side toward the electrode 61 on the X-axis positive side. Accordingly, Lorentz forces are generated in the Z-axis direction at the portions of the wire 60 that are orthogonal to the magnetic fluxes M41 to M43 in the Y-axis positive direction, that is, the portions of the wire 60 that extend in the X-axis direction at a neutral position in FIG. 24. In addition, if the driving parts 250 are in operation when an impact is applied, the controller 201 stops the application of the voltage to each driving part 250.

Thus, in Embodiment 8 as well, displacement of the vibration plate 20 from the neutral position can be suppressed.

### Embodiment 9

In Embodiments 1 to 8, the displacement suppression part which suppresses displacement of the vibration plate 20 from the neutral position by the force generated by the action of the magnet is composed of a wire placed on the vibration plate 20 and a magnet (coil or permanent magnet) that exerts a magnetic flux on the wire. In contrast, in Embodiment 9, the displacement suppression part is composed of a magnet thin film 122 placed on the vibration plate 20 and a magnet (coil or permanent magnet).

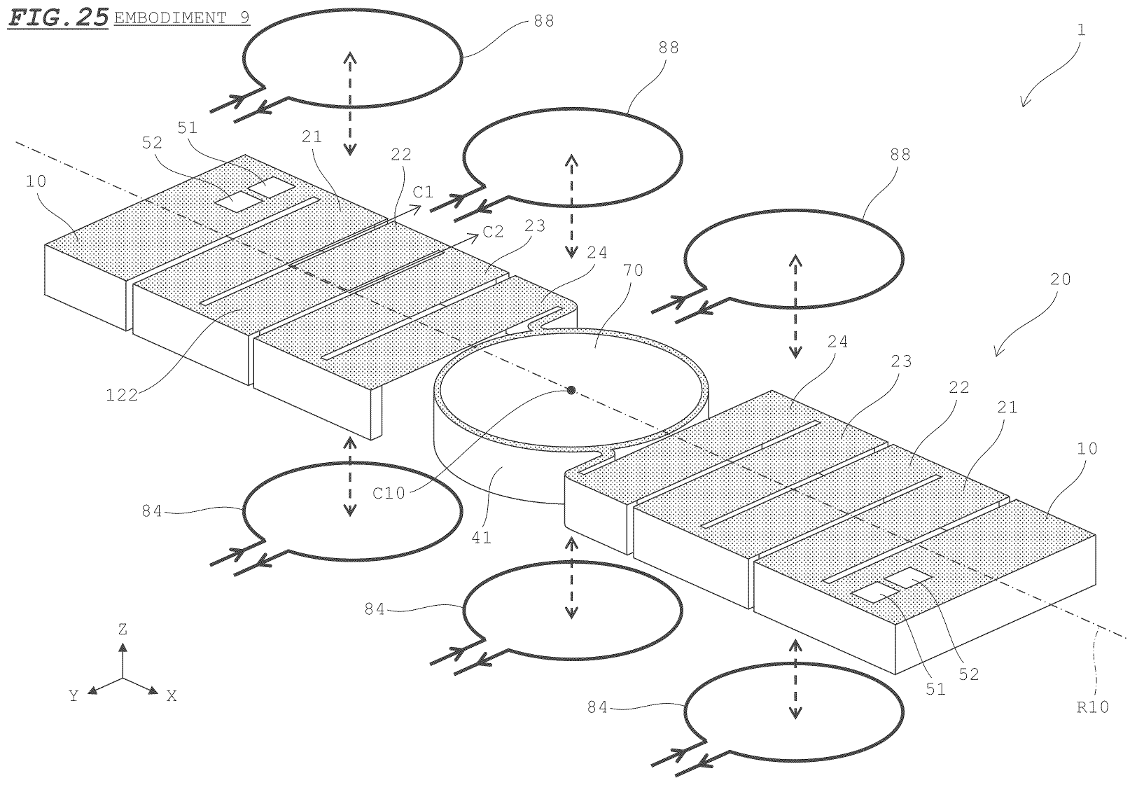

FIG. 25 is a perspective view schematically showing a configuration of a driving element 1 according to Embodiment 9.

In the driving element 1 of Embodiment 9, as compared to the driving element 1 of Embodiment 5 shown in FIG. 17, the magnet thin film 122 and three coils 88 are added instead of the wire 60, the pair of electrodes 61, and the pair of permanent magnets 81.

In manufacturing the driving element 1 of Embodiment 9, an insulating layer 121 is formed on the upper surface of the structure ST1 in FIG. 1, as in FIG. 2. Then, as shown in FIG. 25, the magnet thin film 122 is formed on the entire upper surface of the insulating layer 121. However, the insulating layer 121 and the magnet thin film 122 are not formed on the upper surfaces of the electrodes 51 and 52.

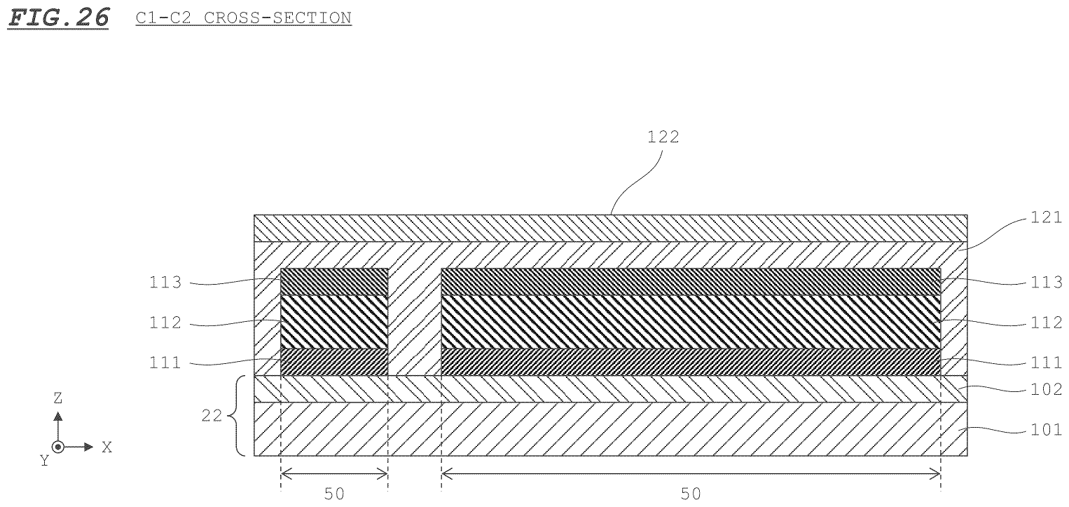

FIG. 26 is a side view schematically showing a C1-C2 cross-section at the vibration part 22 in FIG. 25. The vibration parts 21, 23, and 24 have substantially the same configuration as the vibration part 22, and thus only the vibration part 22 will be described below for convenience.

A base layer 101, an insulating layer 102, driving parts 50 (lower electrode 111, piezoelectric layer 112, and upper electrode 113), and the insulating layer 121 are configured in the same manner as in Embodiment 1 shown in FIG. 3A. On the upper surface of the insulating layer 121, for example, a 3d transition metal such as iron (Fe) or cobalt (Co) is formed by vapor deposition, and then this metal is magnetized by a magnetizing coil, whereby the magnet thin film 122 is formed on the upper surface of the insulating layer 121. At this time, the direction of magnetization of the magnet thin film 122 is set such that the upper surface of the magnet thin film 122 is an N pole and the lower surface of the magnet thin film 122 is an S pole.

Referring back to FIG. 25, a mirror 70 is formed on the upper surface of the magnet thin film 122 formed on the movable part 41. If the upper surface of the magnet thin film 122 formed on the movable part 41 has a sufficient reflectance, the mirror 70 may not necessarily be formed, and the upper surface of the magnet thin film 122 may be used as a reflection surface.

Each coil 88 has the same configuration as each coil 84 of Embodiment 5. The three coils 88 are placed above the vibration plate 20, and are placed at the same positions as the three coils 84 placed below the vibration plate 20 in a plan view. End portions of the three coils 84 and the three coils 88 are connected to the current supply part 205 (see FIG. 6).

The controller 201 controls the current supply part 205 such that when an impact is applied to the driving element 1, currents flow through the three coils 84 and the three coils 88 in predetermined directions. Accordingly, the three coils 84 and the three coils 88 become electromagnets. At this time, the directions of the currents caused to flow through the coils 84 and 88 are set such that magnetic repulsive forces are generated as shown by dashed arrows between the three coils 84 and the lower surface (S pole) of the magnet thin film 122 and magnetic repulsive forces are generated as shown by dashed arrows between the three coils 88 and the upper surface (N pole) of the magnet thin film 122. In the example shown in FIG. 25, currents are caused to flow through the three coils 84 and the three coils 88 in a clockwise direction viewed in the Z-axis negative direction.

If the driving parts 50 are in operation when an impact is applied, the controller 201 stops the application of the voltage to each driving part 50.

The repulsive force generated between each coil 84 and the magnet thin film 122 is adjusted by the distance from the magnet thin film 122 to the coil 84, the number of turns of the coil 84, the magnitude of the current caused to flow through the coil 84, etc. Similarly, the repulsive force generated between each coil 88 and the magnet thin film 122 is adjusted by the distance from the magnet thin film 122 to the coil 88, the number of turns of the coil 88, the magnitude of the current caused to flow through the coil 88, etc.

The position of each coil 84 or 88, the number of turns of each coil 84 or 88, the magnitude of the current caused to flow through each coil 84 or 88, etc., are set such that the magnetic repulsive force applied to the magnet thin film 122 by each coil 84 and the magnetic repulsive force applied to the magnet thin film 122 by each coil 88 are substantially equal to each other when the vibration plate 20 is at the neutral position. However, if the vibration plate 20 can smoothly vibrate and the vibration plate 20 can be braked by the respective magnetic repulsive forces when an impact is applied, these magnetic repulsive forces may not necessarily be equal to each other.

### Effects of Embodiment 9

According to Embodiment 9, the following effects are achieved.

Each driving part 50 is placed on the vibration plate 20 and vibrates the vibration plate 20. The movable part 41 is placed in the vibration plate 20 and is rotated by the vibration of the vibration plate 20. The magnet thin film 122, the three coils 84, and the three coils 88 (displacement suppression part) suppress displacement of the vibration plate 20 from the neutral position by the forces generated by the action of the three coils 84 and the three coils 88 (magnets).

With this configuration, displacement of the vibration plate 20 from the neutral position is suppressed by the forces generated by the action of the magnets. Accordingly, when an impact is applied to the driving element 1, excessive displacement of the movable part 41 can be smoothly suppressed.

The magnet thin film 122 is placed on the vibration plate 20. Displacement of the vibration plate 20 from the neutral position is suppressed by the magnetic repulsive forces generated between the magnet thin film 122 and the three coils 84 and the three coils 88 (magnets).

With this configuration, as shown in FIG. 25, when currents flow through the coils 84 and 88, magnetic repulsive forces are generated between the coils 84 and the magnet thin film 122, and magnetic repulsive forces are generated between the coils 88 and the magnet thin film 122. Accordingly, when an impact is applied to the driving element 1, excessive displacement of the movable part 41 can be smoothly suppressed by causing currents to flow through the coils 84 and 88 to generate the above magnetic repulsive forces.

The three coils 84 and the three coils 88, as magnets, generate magnetic repulsive forces between the magnet thin film 122 and the coils 84 and 88. By adjusting the magnitudes of the currents caused to flow through the coils 84 and 88, the magnitude of the magnetic repulsive forces generated between the magnet thin film 122 and the coils 84 and 88 can be adjusted. Thus, for example, displacement of the movable part 41 can be properly suppressed in accordance with the magnitude of an impact. In addition, since different currents can be caused to flow through the three coils 84 and the three coils 88, respectively, displacement of a portion of the vibration plate 20 for which fluctuations are desired to be suppressed can be suppressed effectively.

In Embodiment 9, a permanent magnet may be placed instead of the coils 84 and 88. When a permanent magnet is used as a magnet instead of coils as described above, the structure and control of the driving element 1 can be simplified.

### Other Modifications

In Embodiments 1, 2, 4, and 5 above, the pair of permanent magnets 81 are placed as magnets, and in Embodiment 8 above, the pairs of permanent magnets 85 to 87 are placed as magnets. However, the present invention is not limited thereto, and one of the pair of permanent magnets may be replaced by a yoke, and the magnet and the yoke may form a magnetic circuit.

In Embodiments 3 to 7 above, the wire 60 is placed in the same manner as in Embodiment 1, but wires 60 may be placed in the same manner as in Embodiment 2. In addition, in Embodiment 8 as well, as in Embodiment 2, wires 260 may be placed so as to extend back and forth from the fixation part 10 to the movable part 241.

In Embodiments 1 to 8 above, the acceleration sensor 90 outputs a signal corresponding to the acceleration caused by an impact applied to the driving element 1, and the controller 201 controls the current supply part 205 based on detection of an impact by the acceleration sensor 90. However, the present invention is not limited thereto, and in the case where the acceleration sensor 90 is capable of individually detecting acceleration in the X, Y, and Z-axis directions, the controller 201 may control the current supply part 205 based on signals corresponding to the acceleration in the X, Y, and Z-axis directions and outputted by the acceleration sensor 90.

For example, in Embodiments 1 to 8, when the controller 201 detects acceleration in the X-axis direction or the Y-axis direction and does not detect acceleration in the Z-axis direction, the controller 201 performs control to apply a current for generating Lorentz forces in the X-axis direction and the Y-axis direction, and does not perform control to apply a current for generating Lorentz forces in the Z-axis direction. When the controller 201 does not detect acceleration in the X-axis direction and the Y-axis direction and detects acceleration in the Z-axis direction, the controller 201 does not perform control to apply a current for generating Lorentz forces in the X-axis direction and the Y-axis direction, and performs control to apply a current for generating Lorentz forces in the Z-axis direction. Accordingly, current control for suppressing displacement of the vibration plate 20 can be efficiently performed.

In Embodiments 1 to 8 above, the vibration plate 20 is composed of silicon (Si), but other materials having flexibility may be used. The driving parts 50 and 250 are configured to include a piezoelectric body as shown in FIG. 3A, but may be configured by a mechanism or the like capable of vibrating the vibration parts 21 to 24 or 221 and 222. The material of each driving part 50 or 250 is not limited to the materials described with reference to FIG. 3A. The wires 60 and 260 are composed of gold (Au), but other materials having conductivity may be used.

In Embodiment 2 above, as shown in FIG. 8, the wires 60 are placed near the end portion on the X-axis negative side and the end portion on the X-axis positive side on the movable part 41, but may not necessarily be placed on the movable part 41 at all. In this case, the wire 60 extending from each electrode 61 is placed so as to be turned back at the connection part 35 and extend to the electrode 62.

In Embodiments 1 to 7 above, the vibration parts 21 to 24 and the connection parts 31 to 35 are placed on the X-axis positive side and the X-axis negative side with the movable part 41 interposed therebetween. That is, a pair of vibration parts are placed with the movable part 41 interposed therebetween. However, the present invention is not limited thereto, and the vibration parts 21 to 24 and the connection parts 31 to 35 may be placed only on either the X-axis positive side or the X-axis negative side. That is, the vibration parts may be placed only on one side of the movable part 41. Similarly, in Embodiment 8 above, the vibration parts 221 and 222 and the connection parts 231 and 232 are placed on the X-axis positive side and the X-axis negative side with the movable part 241 interposed therebetween, but the vibration parts 221 and 222 and the connection parts 231 and 232 may be placed only on either the X-axis positive side or the X-axis negative side.

In Embodiments 1 to 8, the acceleration sensor 90 is placed in order to detect an impact applied to the driving element 1, but the present invention is not limited thereto, and another sensor may be placed instead of the acceleration sensor 90 as long as an impact applied to the driving element 1 can be detected. For example, a strain sensor that detects strain due to an impact applied to the driving element 1 may be placed, or a load sensor that detects a load applied to the driving element 1 may be placed.

In Embodiments 1 to 7 above, in order to generate Lorentz forces based on the magnetic flux M10 in the X-axis direction, the wire 60 is provided with the portions orthogonal to the X-axis direction, but the present invention is not limited thereto, and the wire 60 may not necessarily be provided with any portion orthogonal to the X-axis direction, and only needs to be provided with a portion crossing the X-axis direction. In this case as well, the wire 60 crossing the X-axis direction can generate Lorentz forces in the Z-axis direction based on the magnetic flux M10 in the X-axis direction. In Embodiment 8 above as well, the wire 260 may not necessarily be provided with any portion orthogonal to the Y-axis direction, and only needs to be provided with a portion crossing the Y-axis direction.

For the same reason, in Embodiments 1 to 7 above, the direction of the magnetic flux M10 may be inclined with respect to the X-axis direction. In Embodiments 4 to 7 above, the directions of the magnetic fluxes M20 and M31 to M33 may be inclined with respect to the Z-axis direction. In Embodiment 8 above, the directions of the magnetic fluxes M41 to M43 may be inclined with respect to the Y-axis direction.

In Embodiments 1 to 8 above, the controller 201 controls the current supply part 205 such that currents are caused to flow through the wires 60 and 260 and the coils 82, 83, and 84 when it is determined that an impact has been applied to the driving element 1 based on a detection signal corresponding to the acceleration and outputted from the signal processing part 206. However, the present invention is not limited thereto, and the controller 201 may control the current supply part 205 such that currents are always caused to flow through the wires 60 and 260 and the coils 82, 83, and 84 during operation of the driving element 1.

In Embodiment 5 above, the three coils 84 are placed as shown in FIG. 17, but the number of coils 84 is not limited to three. In addition, in Embodiment 9 above, the three coils 84 and the three coils 88 are placed as shown in FIG. 25, but each of the numbers of coils 84 and 88 is not limited to three.

In Embodiment 9 above, the magnet thin film 122 is formed only on the upper surface side of the vibration plate 20, but a magnet thin film 122 may also be formed on the lower surface side of the vibration plate 20. In this case, each magnet thin film 122 is formed on the vibration plate 20 such that each coil 88 and the upper surface of the magnet thin film 122 formed on the upper surface side repel each other by a magnetic force and each coil 84 and the lower surface of the magnet thin film 122 formed on the lower surface side repel each other by a magnetic force.

In Embodiment 9 above, the vibration plate 20 has a meander shape as shown in FIG. 25, but may have a tuning fork shape as shown in FIG. 24.

In addition to the above, various modifications can be made as appropriate to the embodiments of the present invention, without departing from the scope of the technological idea defined by the claims.

What is claimed is:

1. A driving element comprising:
a fixation part;
a vibration plate supported by the fixation part;
a driving part placed on the vibration plate and configured to vibrate the vibration plate;
a movable part placed in the vibration plate and configured to be rotated by vibration of the vibration plate; and
a displacement suppression part configured to suppress displacement of the vibration plate from a neutral position by a force generated by action of a magnet.

2. The driving element according to claim 1, wherein
the displacement suppression part includes a wire for braking placed on the vibration plate,
the magnet exerts a magnetic flux on the wire, and
when a current flows through the wire, the wire and the magnet generate a Lorentz force that suppresses displacement of the vibration plate from the neutral position.

3. The driving element according to claim 2, wherein the wire is placed along the driving part.

4. The driving element according to claim 3, wherein the wire is placed so as to overlap the driving part.

5. The driving element according to claim 2, wherein the wire is placed on the movable part.

6. The driving element according to claim 5, wherein the wire is placed over substantially an entire range of the movable part.

7. The driving element according to claim 1, wherein
the displacement suppression part includes a magnet thin film placed on the vibration plate, and
displacement of the vibration plate from the neutral position is suppressed by a magnetic repulsive force generated between the magnet thin film and the magnet.

8. The driving element according to claim 1, wherein the magnet includes a permanent magnet.

9. The driving element according to claim 1, wherein the magnet includes a coil.

10. The driving element according to claim 1, wherein a reflection surface is formed on an upper surface of the movable part.

11. The driving element according to claim 1, wherein the driving part includes a piezoelectric body.

12. The driving element according to claim 1, wherein the vibration plate has a meander shape.

13. The driving element according to claim 1, wherein the vibration plate has a tuning fork shape.

14. The driving element according to claim 1, wherein
a pair of the vibration parts are placed with the movable part interposed therebetween, and
the driving part is placed on each of the pair of the vibration parts.

15. A driving device comprising a driving element including:
a fixation part;
a vibration plate supported by the fixation part;
a driving part placed on the vibration plate and configured to vibrate the vibration plate;
a movable part placed in the vibration plate and configured to be rotated by vibration of the vibration plate; and
a displacement suppression part configured to suppress displacement of the vibration plate from a neutral position by a force generated by action of a magnet, wherein
the displacement suppression part includes a wire for braking placed on the vibration plate,
the magnet exerts a magnetic flux on the wire,
when a current flows through the wire, the wire and the magnet generate a Lorentz force that suppresses displacement of the vibration plate from the neutral position, and
the driving device comprises a current supply part configured to supply the current to the wire.

16. The driving device according to claim 15, further comprising:
a sensor configured to detect an impact applied to the driving element; and
a controller configured to control the current supply part based on detection of an impact by the sensor.

17. A driving device comprising a driving element including:
a fixation part;
a vibration plate supported by the fixation part;
a driving part placed on the vibration plate and configured to vibrate the vibration plate;
a movable part placed in the vibration plate and configured to be rotated by vibration of the vibration plate; and
a displacement suppression part configured to suppress displacement of the vibration plate from a neutral position by a force generated by action of a magnet, wherein
the displacement suppression part includes a magnet thin film placed on the vibration plate,
displacement of the vibration plate from the neutral position is suppressed by a magnetic repulsive force generated between the magnet thin film and the magnet,
the driving device comprises a current supply part,
the magnet includes a coil, and
the current supply part supplies a current to the coil.

18. The driving device according to claim 17, further comprising:
a sensor configured to detect an impact applied to the driving element; and
a controller configured to control the current supply part based on detection of an impact by the sensor.
